(19) United States
(12) Patent Application Publication
(10) Pub. No.: US 2026/0221383 A1
(43) Pub. Date: Jul. 30, 2026

(54) A NEW DESIGN CONCEPT OF SCANNING ELECTRON MICROSCOPE WITH CHARGED PARTICLE SOURCE

(71) Applicant: ASML Netherlands B.V., Veldhoven (NL)

(72) Inventors: Oleg KRUPIN, Mountain View, CA (US); Zizhou GONG, San Jose, CA (US); Weiming REN, San Jose, CA (US); Xuerang HU, San Jose, CA (US); Yongxin WANG, San Ramon, CA (US)

(73) Assignee: ASML Netherlands B.V., Veldhoven (NL)

(21) Appl. No.: 19/141,484

(22) PCT Filed: Dec. 19, 2023
(86) PCT No.: PCT/EP2023/086733

§ 371 Date: Jun. 20, 2025

Related U.S. Application Data
(60) Provisional application No. 63/434,328, filed on Dec. 21, 2022.
(60) Provisional application No. 63/608,112, filed on Dec. 8, 2023.

(51) Int. Cl. H01J 37/28; H01J 37/22; H01J 37/244; H01J 37/26

(52) U.S. Cl. CPC H01J 37/28; H01J 37/222; H01J 37/244; H01J 37/265; H01J 2237/24528; H01J 2237/24535

(57) ABSTRACT

A particle beam inspection apparatus, and more particularly, a method of particle beam parameter variation compensation for image inspection and enhancement are disclosed. A primary beam emission current may be continuously monitored to compensate for an emission current fluctuation. The fluctuation may be compensated by adjusting a characteristic of the electron source or a sub-system within the charged particle system. An event-based detection system may be used to measure a number of electrons impacting a detector within a period of time with a location on a sample and normalize a generated image of the sample. A deflector may adjust a deflection speed of the primary beam across the sample to compensate for emission current fluctuation while maintaining a constant dose impacting a sample. Thus, image quality is improved, sources of error during sample inspection are minimized, metrology measurement accuracy is improved, and throughput is increased.

### CROSS-REFERENCE TO RELATED APPLICATIONS

This application claims priority of U.S. application 63/434,328 which was filed on Dec. 21, 2022 and U.S. application 63/608,112 which was filed on Dec. 8, 2023 which are incorporated herein in its entirety by reference.

### FIELD

The embodiments provided herein relate to charged particle beam emission variation compensation technology. A charged particle beam system may be used to continuously compensate fluctuations in charged-particle beam emission and resolve image performance issues related to charged particle beam emission fluctuations.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become increasingly important. Inspection images such as SEM images can be used to identify or classify defects of the manufactured ICs. Improvements to detection performance, image quality, or throughput of the inspection systems are desired.

### SUMMARY

The embodiments provided herein disclose a charged-particle beam inspection apparatus, and more particularly, a method of charged-particle beam parameter variation compensation, inspection image acquisition, and inspection image enhancement.

Some embodiments provide an apparatus for inspecting a sample. The apparatus comprises a charged particle source configured to emit a primary beam of charged particles, an aperture substrate comprising a first set of apertures configured to form a first set of charged particle beamlets by passing through a portion of charged particles of the primary beam of charged particles, and a second aperture configured to form a second charged particle beamlet by passing through another portion of charged particles of the primary beam of charged particles, wherein the second charged particle beamlet is active at a same time as the first set of charged particle beamlets, and the first set of charged particle beamlets and second charged particle beamlets have no beamlet in common, one or more first detectors to detect secondary charged particles emitted in response to the first set of charged particle beamlets impacting the sample, an auxiliary detector configured to monitor the second charged particle beamlet, wherein the second charged particle beamlet is directed to the auxiliary detector without interacting with the sample, and an image processor configured to generate an image based on detection data from the one or more first detectors and based on detection data from the auxiliary electron detector.

In some embodiments, a non-transitory computer readable medium storing a set of instructions that is executable by one or more processors of a charged particle beam apparatus to cause the charged particle beam apparatus to perform a method of inspecting a sample is provided. The method comprises causing a charged particle source to emit a primary beam of charged particles, forming a first set of charged particle beamlets using a first set of apertures on an aperture substrate by passing a portion of charged particles of the primary beam of charged particles through the first set of apertures, wherein secondary charged particles emitted in response to the first set of charged particle beamlets impacting the sample are detected by one or more first detectors, focusing the first set of charged particle beamlets using an objective lens to a focal point substantially at the sample, forming a second charged particle beamlet using a second aperture on the aperture substrate by passing a portion of charged particles of the primary beam of charged particles through the second aperture, wherein the second charged particle beamlet is active at a same time as the first set of charged particle beamlets and is directed to an auxiliary detector without interacting with the sample, and the first set of charged particle beamlets and the second charged particle beamlet have no beamlet in common, and generating an image based on detection data from the one or more first detectors and based on detection data from the auxiliary detector.

Other advantages of the embodiments of the present disclosure will become apparent from the following description taken in conjunction with the accompanying drawings wherein are set forth, by way of illustration and example, certain embodiments of the present disclosure.

### BRIEF DESCRIPTION OF FIGURES

The above and other aspects of the present disclosure will become more apparent from the description of exemplary embodiments, taken in conjunction with the accompanying drawings.

FIG. 1 is a schematic diagram illustrating an example charged-particle beam inspection system, consistent with embodiments of the present disclosure.

FIG. 2 is a schematic diagram illustrating an example single-beam electron beam inspection (EBI) system consistent with embodiments of the present disclosure.

FIG. 3 is a schematic diagram of an example multi-beam tool, consistent with embodiments of the present disclosure.

FIG. 4 is an example schematic of a charged particle system to monitor and compensate fluctuations in a charged particle beam, consistent with embodiments of the present disclosure

FIG. 5 which is an example schematic of a system to compensate emission fluctuations in a charged particle source, consistent with embodiments of the present disclosure.

FIGS. 6A, 6B are schematic diagrams illustrating an example multi-beam inspection tool that can form a plurality of first electron beamlets and one or more second electron beamlets, and an aperture substrate with an example configuration array of apertures, consistent with embodiments of the present disclosure.

FIG. 7 is a schematic diagram illustrating a top-view of a surface of an example auxiliary detector, consistent with embodiments of the present disclosure.

FIGS. 8A, 8B are schematic diagrams illustrating an aperture substrate with example configurations of a first aperture array and a plurality of second apertures, consistent with embodiments of the present disclosure.

FIGS. 9A, 9B, 9C, 9D, 9E are schematic diagrams illustrating various example aperture substrate configurations of a second aperture array positioned between a first aperture array, consistent with embodiments of the present disclosure.

FIGS. 10A, 10B, 10C, 10D are schematic diagrams illustrating various locations of one or more auxiliary detectors, which are consistent with embodiments of the present disclosure.

FIG. 11A is a schematic diagram illustrating various scan lines of an electron beam across a sample surface applied by a charged particle beam apparatus, consistent with embodiments of this present disclosure.

FIG. 11B is an example illustration of an electrical signal applied to a charged particle beam deflector over time on a sample, consistent with embodiments of the present disclosure.

FIGS. 12A and 12B are example schematic representations of detection systems, consistent with embodiments of the present disclosure.

FIG. 13 is an example illustration of a field of view with a pixel associated with an electron landing event and timestamp, consistent with embodiments of the present disclosure.

FIG. 14 is a flowchart representing an example process for compensating electron beam variations in generating a SEM image, consistent with embodiments of the present disclosure.

FIG. 15 is an example illustration of dynamically adjusting scanning of a primary beam of charged particles across a sample to compensate for a variation in a charged particle source, consistent with embodiments of the present disclosure.

FIG. 16 is a flowchart representing an example process for compensating electron beam variations in generating a SEM image, consistent with embodiments of the present disclosure.

FIG. 17 is a flowchart representing an example process for compensating variations in electron beam current in generating an SEM image, consistent with embodiments of the present disclosure.

FIG. 18 is an example illustration of a longer duration of a charged particle apparatus for inspection or metrology, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged-particle beams (e.g., including protons, ions, muons, or any other particle carrying electric charges) may be similarly applied. Furthermore, other imaging systems may be used, including but not limited to, optical imaging, photon detection, x-ray detection, ion detection, etc.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fitted on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using an inspection tool such as, for example, a scanning charged-particle microscope (SCPM). For example, an SCPM may be a scanning electron microscope (SEM). A SCPM inspection tool can be used to image these extremely small structures, in effect, taking a “picture” of the structures of the wafer to generate an inspection image. The inspection image can be used to determine if the structure was formed properly in the proper location. If the structure is defective, then the process can be adjusted, so the defect is less likely to recur.

As the physical sizes of IC components continue to shrink, accuracy and yield in defect detection become more important. Inspection images such as SCPM images can be used for metrology measurements (e.g., to identify or classify defects) of the manufactured ICs. Measurements including, but not limited to, critical dimensions of the inspection image may be used to identify defects on the wafer. It is desired to obtain images that are accurately focused, have high-quality contrast, and improved signal-to-noise ratios, so inspection and metrology measurements may be accurate. One way to improve the quality of images may be to monitor and obtain parameter information of the charged-particle beam during imaging and correct any deviation of the parameter of the charged particle beam from a threshold value.

For example, an SEM scans the surface of a sample with a focused beam of primary electrons. The primary electrons interact with the sample and generate secondary electrons. By scanning the sample with the focused beam and capturing the secondary electrons with a detector, the SEM creates an image of the scanned area of the sample. For high throughput inspection, some of the inspection systems use multiple focused beams of primary electrons. As the multiple focused beams can scan different parts of a sample at the same time, multi-beam inspection system can inspect a sample at a much higher speed than a single-beam inspection system.

In a conventional multi-beam inspection system, however, increasing the number of focused beams means that more off-axis (i.e., not on a primary optical axis of the system) focused beams are employed. An off-axis focused beam may have aberrations that increase with its radial shift from the primary optical axis, and therefore degrades the quality of images that are produced for inspection. This aberration increase is, in some cases, a consequence of the directions of some of the electron beams needing to be changed substantially to scan the surface of the sample. When the number of electron beams are increased, some of the electron beams need to be routed away from the central axis of the scanning device. To ensure all electron beams arrive at the surface of the sample at the right angle, these off-center electron beams are manipulated more than the other electron beams around the central axis. This higher level of manipulation may cause blurry and out-of-focus images of the sample.

In a SEM, primary electrons are generated by an electron gun (also called an electron source). In the source, the primary electrons are created using electron emission from the cathode tip; then, they are accelerated to the energies necessary for transporting them through the electron-optical system of SEM to the sample. The electron source may be of thermal emission, field emission, or Schottky (field enhanced thermionic) emission types. To obtain high-quality images of the sample, keeping the primary electron beam consistent and stable is critical. Electron sources, however, may show short- and long-term fluctuations and drift of the emission current. The primary beam from the electron source may exhibit changes in the angular distribution of the emitted current density and the virtual source position. These fluctuations may affect the stability of the primary electron beamlets hitting the surface of the sample and lead to variation of the secondary electron signal collected from the imaged surface, which ultimately affects the image quality and reproducibility of the images. When the primary beam emission current deviates past a threshold value, this may necessitate a shut-down of the SEM to “reset” the electron source stability. Thus, throughput is decreased.

Embodiments of the disclosure may provide a charged-particle beam parameter variation compensation method to correct electron source and electron beamlet fluctuations. Some embodiments of the disclosure may provide an electron beamlet that may be continuously monitored for fluctuations and is separate from electron beamlets used for imaging a sample. The fluctuations monitored via the separate electron beamlet may be used to compensate for fluctuations of the electron beamlets used to image a sample. Such fluctuations may result from, for example, fluctuations of the electron source. Some embodiments of the disclosure may provide a system to continuously monitor a primary beam emission current and compensate for a fluctuation in emission current. The system may compensate for a fluctuation by adjusting a characteristic of the electron source or a sub-system within the charged particle system. In some embodiments, an event-based detection system is used to associate a number of electrons impacting a detector within a period of time with a location on a sample. The event-based detection system may facilitate back-calculating a compensation signal to provide to the electron source or the sub-system of the charged particle system. In some embodiments, the compensation signal may adjust a deflection speed of the primary beam across the sample. In some embodiments, the compensation signal may normalize a generated image of the sample. This real time compensation may be used to adjust an image to improve the image quality, such as by removing unwanted noise in the image resulting from the forementioned fluctuations, enabling improved accuracy images and associated improved accuracy metrology based on these images. Additionally, embodiments of the present disclosure may allow for a SEM to compensate for greater variations in primary beam emission current and reduce a frequency of SEM shut-down to “reset” electron source stability. Thus, embodiments of the disclosure may improve the quality of a generated image of a sample, minimize sources of error during sample inspection, improve metrology measurement accuracy, and increase throughput.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

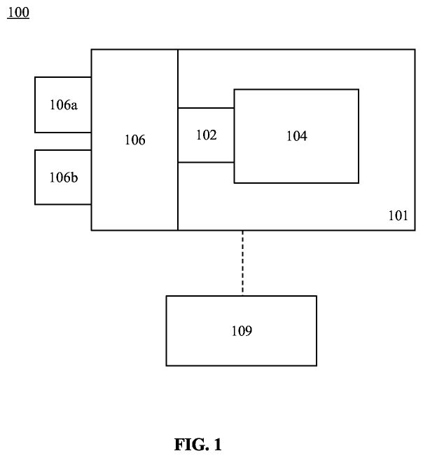

FIG. 1 illustrates an example electron beam inspection (EBI) system 100 consistent with embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive sample front opening unified pods (FOUPs) that contain samples (e.g., semiconductor wafers or wafers made of other material(s)). A “lot” is a plurality of samples that may be loaded for processing as a batch.

One or more robotic arms (not shown) in EFEM 106 may transport the samples to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the sample from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the sample is subject to inspection by beam tool 104. Beam tool 104 may be a single-beam system or a multi-beam system.

A controller 109 is electronically connected to beam tool 104. Controller 109 may be a computer configured to execute various controls of EBI system 100. Controller 109 may also include processing circuitry configured to execute various signal and image processing functions. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, a hardware accelerator, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

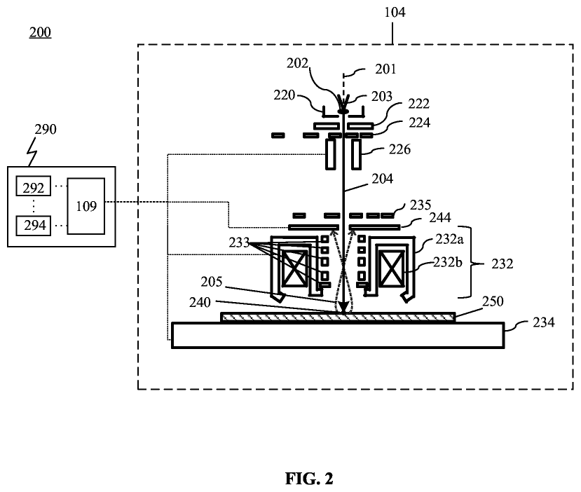

Reference is now made to FIG. 2, which is a schematic diagram illustrating an example imaging system 200, comprising an electron beam tool 104 and an image processing system 290, consistent with embodiments of the present disclosure. As shown in FIG. 2, electron beam tool 104 may include a motorized stage 234 to support a sample 250 to be inspected. Electron beam tool 104 may further include an objective lens 232, electron detector 244 (which includes electron sensor surfaces), a condenser lens 226, a Coulomb aperture 224, a gun aperture 222, an anode 220, and a cathode 203, one or more of which may be aligned with an optical axis 201 of electron beam tool 104. In some embodiments, detector 244 may be arranged off optical axis 201.

Objective lens 232, may include a modified swing objective retarding immersion lens (SORIL), which may include an objective lens body 232a, and an objective exciting coil 232b. Within objective lens 232 may be a deflector or a set of deflectors 233. Electron beam tool 104 may additionally include an energy dispersive X-ray spectrometer (EDS) detector (not shown) to characterize the materials on the sample.

A primary electron beam 204 may be emitted from cathode 203 by applying a voltage between anode 220 and cathode 203. Primary electron beam 204 may pass through gun aperture 222 and Coulomb aperture 224, both of which may determine the current of primary electron beam 204 entering condenser lens 226, which resides below Coulomb aperture 224. Condenser lens 226 may focus primary electron beam 204 before the beam enters current-limiting aperture 235 to set the current of the electron beam before entering objective lens 232. The set current of primary electron beam 204 entering objective lens 232 may be referred to as the probe current.

Objective lens 232 may focus primary electron beam 204 onto sample 250 for inspection and can form a probe spot 240 on surface of sample 250. Deflector(s) 233 may deflect primary electron beam 204 to scan probe spot 240 over sample 250. For example, in a scanning process, deflector(s) 233 may be controlled to deflect primary electron beam 204 sequentially onto different locations of top surface of sample 250 at different time points, to provide data for image reconstruction for different parts of sample 250. Moreover, deflectors 233 may also be controlled to deflect primary electron beam 204 onto different sides of sample 250 at a particular location, at different time points, to provide data for stereo image reconstruction of the sample structure at that location.

When an electric signal is applied to objective exciting coil 232b, an axially-symmetric (i.e., symmetric around optical axis 201) magnetic field may be generated in the sample surface area. A part of sample 250 being scanned by primary electron beam 204 may be immersed in the magnetic field. Different voltages may be applied onto sample 250 to generate an axial symmetric retarding electrostatic field near the sample surface. The electrostatic field may reduce the energy of impinging primary electron beam 204 near the surface of the sample before electrons of the beam collide with sample 250.

Secondary electrons 205 may be emitted from the part of sample 250 upon receiving primary electron beam 204. While not illustrated in FIG. 2, it is appreciated that primary electron beam 204 impacting sample 250 may also generate backscattered electrons or Auger electrons. Secondary electrons 205 may be received by sensor surfaces of electron detector 244. In some embodiments, electron detector 244 may generate a signal (e.g., a voltage, a current, etc.) that represents an intensity of emitted secondary electrons 205 and may provide the signal to image processing system 290 in communication with electron detector 244. The intensity of secondary electrons 205 emitted may vary according to the external or internal structure of sample 250, and thus may indicate whether sample 250 includes defects. Moreover, as discussed above, primary electron beam 204 may be projected onto different locations of the top surface of sample 250, or different sides of sample 250 at a particular location, to generate secondary electrons 205 of different intensities. Therefore, by mapping the intensity of secondary electrons 205 emitted with the areas of sample 250, image processing system 290 may reconstruct an image that reflects the characteristics of internal or external structures of sample 250.

Imaging system 200 may also comprise image processing system 290 that includes an image acquirer 292, a storage 294, and controller 109. Image acquirer 292 may comprise one or more processors. For example, image acquirer 292 may comprise a computer, server, mainframe host, terminals, personal computer, any kind of mobile computing devices, and the like, or a combination thereof. Image acquirer 292 may be communicatively coupled to a detector 244 of electron beam tool 104 through a medium such as an electrical conductor, optical fiber cable, portable storage media, IR, Bluetooth, internet, wireless network, wireless radio, or a combination thereof. Image acquirer 292 may receive a signal from detector 244 and may construct an image. Image acquirer 292 may thus acquire images of sample 250. Image acquirer 292 may also perform various post-processing functions, such as generating contours, superimposing indicators on an acquired image, and the like. Image acquirer 292 may be configured to perform adjustments of brightness and contrast, etc. of acquired images. Storage 294 may be a storage medium such as a hard disk, flash drive, cloud storage, random access memory (RAM), other types of computer readable memory, and the like. Storage 294 may be coupled with image acquirer 292 and may be used for saving scanned raw image data as original images, and post-processed images. Image acquirer 292 and storage 294 may be connected to controller 109. Image acquirer 292, storage 294, and controller 109 may be integrated together as one control unit.

Image acquirer 292 may acquire one or more images of a sample based on an imaging signal received from detector 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of sample 250. The acquired images may comprise multiple images of a single imaging area of sample 250 sampled multiple times over a time sequence. The multiple images may be stored in storage 294. Image processing system 290 may be configured to perform image processing steps with the multiple images of the same location of sample 250.

Image processing system 290 may include measurement circuitries (e.g., analog-to-digital converters) to obtain a distribution of the detected secondary electrons. The electron distribution data collected during a detection time window, in combination with corresponding scan path data of primary electron beam 204 incident on the sample surface, can be used to reconstruct images of the sample structures under inspection. The reconstructed images can be used to reveal various features of the internal or external structures of sample 250, and thereby can be used to reveal any defects that may exist in the sample.

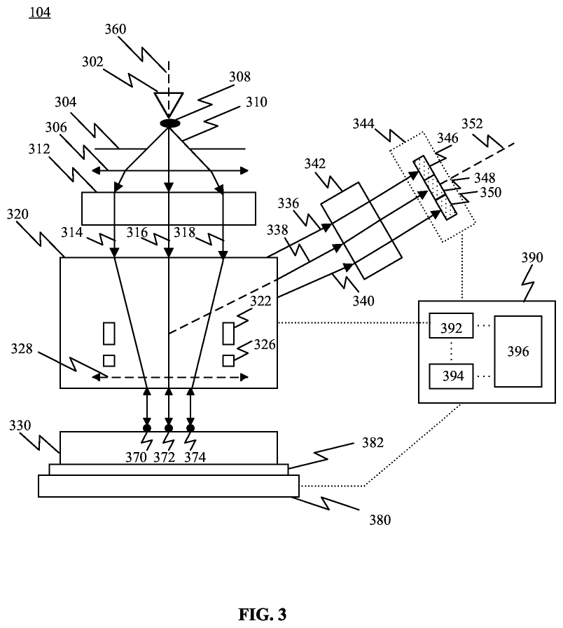

FIG. 3 illustrates a schematic diagram of an example multi-beam tool 104 (also referred to herein as apparatus 104) and an image processing system 390 that may be configured for use in EBI system 100 (FIG. 1), consistent with embodiments of the present disclosure. Beam tool 104 comprises a charged-particle source 302, a gun aperture 304, a condenser lens 306, a primary charged-particle beam 310 emitted from charged-particle source 302, a source conversion unit 312, a plurality of beamlets 314, 316, and 318 of primary charged-particle beam 310, a primary projection optical system 320, a motorized stage 380, a sample holder 382, multiple secondary charged-particle beams 336, 338, and 340, a secondary optical system 342, and a charged-particle detection device 344. Primary projection optical system 320 may comprise a beam separator 322, a deflection scanning unit 326, and an objective lens 328. Charged-particle detection device 344 may comprise detection sub-regions 346, 348, and 350.

Charged-particle source 302, gun aperture 304, condenser lens 306, source conversion unit 312, beam separator 322, deflection scanning unit 326, and objective lens 328 may be aligned with a primary optical axis 360 of apparatus 104. Secondary optical system 342 and charged-particle detection device 344 may be aligned with a secondary optical axis 352 of apparatus 104.

Charged-particle source 302 may emit one or more charged particles, such as electrons, protons, ions, muons, or any other particle carrying electric charges. In some embodiments, charged-particle source 302 may be an electron source. For example, charged-particle source 302 may include a cathode, an extractor, or an anode, wherein primary electrons may be emitted from the cathode and extracted or accelerated to form primary charged-particle beam 310 (in this case, a primary electron beam) with a crossover (virtual or real) 308. For ease of explanation without causing ambiguity, electrons are used as examples in descriptions herein. However, it should be noted that any charged particle may be used in any embodiment of this disclosure, which is not limited to electrons. Primary electron beam 310 may be visualized as being emitted from crossover 308. Gun aperture 304 may block off peripheral electrons of primary electron beam 310 to reduce Coulomb effect. The Coulomb effect may cause an increase in size of probe spots.

Source conversion unit 312 may comprise an array of image-forming elements and an array of beam-limit apertures. The array of image-forming elements may comprise an array of micro-deflectors or micro-lenses. The array of image-forming elements may form a plurality of parallel images (virtual or real) of crossover 308 with a plurality of beamlets 314, 316, and 318 of primary electron beam 310. The array of beam-limit apertures may limit the plurality of beamlets 314, 316, and 318. While three beamlets 314, 316, and 318 are shown in FIG. 2, embodiments of the present disclosure are not so limited. For example, in some embodiments, apparatus 104 may be configured to generate a first number of beamlets. In some embodiments, the first number of beamlets may be in a range from 1 to 10000. Controller 109 may be connected to various parts of electron beam inspection system 100 of FIG. 1, such as, but not limited to, source conversion unit 312, electron detection device 344, primary projection optical system 320, or motorized stage 380. In some embodiments, controller 109 may perform various image and signal processing functions. Controller 109 may also generate various control signals to govern operations of the electron beam inspection system.

Condenser lens 306 may collimate primary electron beam 310. The electric currents of beamlets 314, 316, and 318 down-beam of source conversion unit 312 may be varied by adjusting the focusing power of condenser lens 306 or by changing the radial sizes of the corresponding beam-limit apertures within the array of beam-limit apertures. Objective lens 328 may focus beamlets 314, 316, and 318 onto a sample 330 for imaging, and may form a plurality of probe spots 370, 372, and 374 on a surface of sample 330.

Beam separator 322 may be a beam separator of Wien filter type generating an electrostatic dipole field and a magnetic dipole field. In some embodiments, if they are applied, the force exerted by the electrostatic dipole field on an electron of beamlets 314, 316, and 318 may be substantially equal in magnitude and opposite in a direction to the force exerted on the electron by magnetic dipole field. Beamlets 314, 316, and 318 may, therefore, pass straight through beam separator 322 with zero deflection angle. However, the total dispersion of beamlets 314, 316, and 318 generated by beam separator 322 may also be non-zero. Beam separator 322 may separate secondary electron beams 336, 338, and 340 from beamlets 314, 316, and 318 and direct secondary electron beams 336, 338, and 340 towards secondary optical system 342.

Deflection scanning unit 326 may deflect beamlets 314, 316, and 318 to scan probe spots 370, 372, and 374 over a surface area of sample 330. In response to the incidence of beamlets 314, 316, and 318 at probe spots 370, 372, and 374, secondary electron beams 336, 338, and 340 may be emitted from sample 330. Secondary electron beams 336, 338, and 340 may comprise electrons with a distribution of energies. For example, secondary electron beams 336, 338, and 340 may include secondary electrons (energies ≤50 eV) and backscattered electrons (energies between 50 eV and landing energies of beamlets 314, 316, and 318). Secondary optical system 342 may focus secondary electron beams 336, 338, and 340 onto detection sub-regions 346, 348, and 350 of electron detection device 344. Detection sub-regions 346, 348, and 350 may be configured to detect corresponding secondary electron beams 336, 338, and 340 and generate corresponding signals (e.g., voltage or current) used to reconstruct an image of structures on or underneath the surface area of sample 330. The generated corresponding signals may also include a spectrum of frequencies, wherein a low-frequency regime contains information about larger features of sample 330 and a high-frequency regime contains information about finer (i.e., sharper) features of sample 330.

The generated signals may represent intensities of secondary electron beams 336, 338, and 340 and may be provided to image processing system 390 that is in communication with electron detection device 344, primary projection optical system 320, and motorized sample stage 380. The movement speed of motorized sample stage 380 may be synchronized and coordinated with the beam deflections controlled by deflection scanning unit 326, such that the movement of the scan probe spots (e.g., scan probe spots 370, 372, and 374) may orderly cover regions of interests on the sample 330. The parameters of such synchronization and coordination may be adjusted to adapt to different materials of sample 330. For example, different materials of sample 330 may have different resistance-capacitance characteristics that may cause different signal sensitivities to the movement of the scan probe spots.

The intensity of secondary electron beams 336, 338, and 340 may vary according to the external or internal structure of sample 330, and thus may indicate whether sample 330 includes defects. Moreover, as discussed above, beamlets 314, 316, and 318 may be projected onto different locations of the top surface of sample 330, or different sides of local structures of sample 330, to generate secondary electron beams 336, 338, and 340 that may have different intensities. Therefore, by mapping the intensity of secondary electron beams 336, 338, and 340 with the areas of sample 330, image processing system 390 may reconstruct an image that reflects the characteristics of internal or external structures of sample 330.

In some embodiments, image processing system 390 may include an image acquirer 392, a storage 394, and a controller 396. Image acquirer 392 may comprise one or more processors. For example, image acquirer 392 may comprise a computer, server, mainframe host, terminals, personal computer, any other appropriate mobile computing devices. Image acquirer 392 may be communicatively coupled to electron detection device 344 of apparatus 104 through a medium such as an electric conductor, optical fiber cable, portable storage media, IR, Bluetooth, internet, wireless network, or wireless radio. In some embodiments, image acquirer 392 may receive a signal from electron detection device 344 and may construct an image. Image acquirer 392 may thus acquire SEM images of sample 330. Image acquirer 392 may also perform various post-processing functions, including, but not limited to, generating contours and superimposing indicators on an acquired image. Image acquirer 392 may be configured to perform adjustments of brightness and contrast of acquired images. In some embodiments, storage 394 may be a storage medium including, but not limited to, a hard disk, flash drive, cloud storage, random access memory (RAM), or other types of computer-readable memory. Storage 394 may be coupled with image acquirer 392 and may be used for saving scanned raw image data as original images and post-processed images. Image acquirer 392 and storage 394 may be connected to controller 396. In some embodiments, image acquirer 392, storage 394, and controller 396 may be integrated together as one control unit.

In some embodiments, image acquirer 392 may acquire one or more SEM images of a sample based on an imaging signal received from electron detection device 344. An imaging signal may correspond to a scanning operation for conducting charged particle imaging. An acquired image may be a single image comprising a plurality of imaging areas. The single image may be stored in storage 394. The single image may be an original image that may be divided into a plurality of regions. Each of the regions may comprise one imaging area containing a feature of sample 330. The acquired images may comprise multiple images of a single imaging area of sample 330 sampled multiple times over a time sequence. The multiple images may be stored in storage 394. In some embodiments, image processing system 390 may include circuitry configured to perform image processing steps with the multiple images of the same location of sample 330.

In some embodiments, image processing system 390 may include measurement circuitry (e.g., analog-to-digital converters) configured to obtain a distribution of the detected secondary electrons. The electron distribution data collected during a detection time window, in combination with corresponding scan path data of beamlets 314, 316, and 318 incident on the sample surface, may be used to reconstruct images of the sample structures under inspection. The reconstructed images may be used to reveal various features of the internal or external structures of sample 230, and thereby may be used to reveal any defects that may exist in the sample.

When electrons of primary electron beam 310 are projected onto a surface of sample 330 (e.g., probe spots 370, 372, and 374), the electrons of primary electron beam 310 may penetrate the surface of sample 330 for a certain depth, interacting with particles of sample 330. Some electrons of primary electron beam 310 may elastically interact with (e.g., in the form of elastic scattering or collision) the materials of sample 330 and may be reflected or recoiled out of the surface of sample 330. An elastic interaction conserves the total kinetic energies of the bodies (e.g., electrons of primary electron beam 310) of the interaction, in which the kinetic energy of the interacting bodies does not convert to other forms of energy (e.g., heat or electromagnetic energy). Such reflected electrons generated from elastic interaction may be referred to as backscattered electrons (BSEs). Some electrons of primary electron beam 310 may inelastically interact with (e.g., in the form of inelastic scattering or collision) the materials of sample 330. An inelastic interaction does not conserve the total kinetic energies of the bodies of the interaction, in which some or all of the kinetic energy of the interacting bodies converts to other forms of energy. For example, through the inelastic interaction, the kinetic energy of some electrons of primary electron beam 310 may cause electron excitation and transition of atoms of the materials. Such inelastic interaction may also generate electrons exiting the surface of sample 330, which may be referred to as secondary electrons (SEs). Yield or emission rates of BSEs and SEs may depend on the material under inspection and the landing energy of the electrons of primary electron beam 310 landing on the surface of the material, among other factors. The energy of the electrons of primary electron beam 310 may be imparted in part by its acceleration voltage (e.g., the acceleration voltage between the anode and cathode of electron source 302 in FIG. 3). The quantity of BSEs and SEs may be more or fewer (or even the same) than the injected electrons of primary electron beam 310.

While FIG. 3 shows detection device 344 having several detection sub-regions aligned with secondary optical axis 352, it is appreciated that other multi-beam detector schemes may exist. For example, it is appreciated that a detector may correspond with each beamlet, such as a different detector for each of beamlets 314, 316, 318. It is appreciated that these different detectors may be positioned under the primary column corresponding to primary axis 360. For example, these different detectors could be positioned between primary projection optical system 320 and the sample stage.

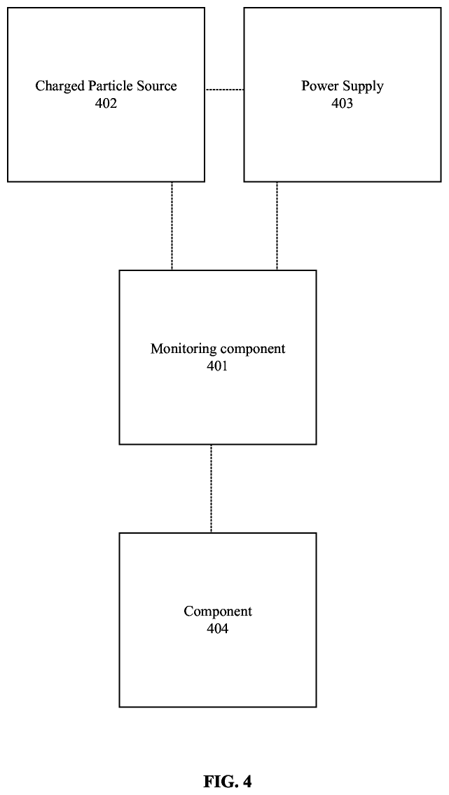

Reference is now made to FIG. 4, which is an example schematic of a charged particle system to monitor and compensate fluctuations in a charged particle beam, consistent with embodiments of the present disclosure. FIG. 4 illustrates that a charged particle source 402 and a monitoring component 401 may be communicatively coupled. In some embodiments, charged particle source 402 and monitoring component 401 may be communicatively coupled to an electron detection device (e.g., electron detection device 344 in FIG. 3) through a medium such as an electric conductor, optical fiber cable, portable storage media, IR, Bluetooth, internet, wireless network, or wireless radio. In some embodiments, monitoring component 401 may measure a signal supplied to charged particle source 402 by a power supply 403 to cause charged particle source 402 to emit a primary beam of charged particles. In some embodiments, monitoring component 401 may measure a characteristic of charged particle source 402. In some embodiments, the measured characteristic of charged particle source 402 may be a fluctuation of charged particle source 402. In some embodiments, monitoring component 401 may monitor a characteristic of charged particle source 402 and be positioned at a downstream location in a charged particle system. In some embodiments, monitoring component 401 may be a controller (e.g., controller 109 in FIG. 1 and FIG. 2 or controller 396 in FIG. 3) or electronic equipment. Monitoring component 401 may monitor a characteristic of the emitted primary charged particle beam, a characteristic of charged particle source 402, or a characteristic of power supply 403. In some embodiments, the characteristic of the emitted primary charged particle beam is a characteristic that reflects an emission characteristic of the emitted primary charged particle beam. In some embodiments, the characteristic of the emitted primary charged particle beam is an electrical signal. In some embodiments, the characteristic of the emitted primary charged particle beam is a fluctuation of an emission current or a fluctuation of a voltage. In some embodiments, the characteristics of power supply 403 may include a fluctuation of an electrical signal supplied to charged particle source 402. In some embodiments, the electrical signal may be a voltage or a current. Monitoring component 401 may determine if the monitored characteristic deviates from a threshold value. For example, monitoring component 401 may determine if the monitored characteristic of power supply 403 (e.g., a fluctuation of a voltage signal supplied to charged particle source 502) has a deviation outside a threshold value. In some embodiments, monitoring component 401 may adjust the deviated characteristic and apply the adjusted characteristic to a component 404 of the charged particle system to compensate for the deviated characteristic. Component 404 may be a component that affects a charged particle beam emission or emission characteristic. In some embodiments, component 404 may be a condenser lens, a stigmator, an objective lens, a deflector, a component of charged particle source 402, a component of power supply 403, or any other component in a charged particle system that may alter a charged particle beam emission.

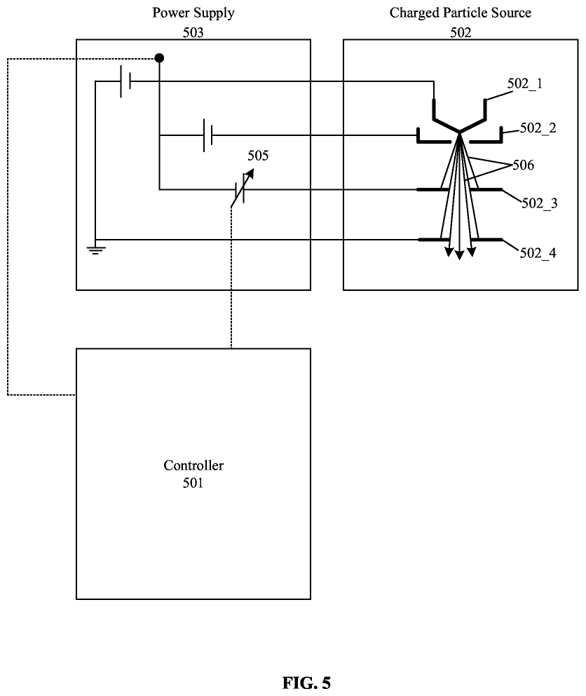

In some embodiments, a monitoring component may be a controller. In some embodiments, the controller may monitor a power supply that supplies a signal to a charged particle source to cause the charged particle source to emit a primary beam of charged particles. In some embodiments, the controller may monitor a charged particle source that emits a primary beam of charged particles. Reference is now made to FIG. 5, which is an example schematic of a system to compensate emission current fluctuations in a charged particle source, consistent with embodiments of the present disclosure. FIG. 5 illustrates that a controller 501 may be communicatively coupled to a charged particle source 502 or a power supply 503. In some embodiments, power supply 503 may be communicatively coupled to a charged particle source cathode 502_1, a suppressor 502_2, an extractor 502_3, or a charged particle source anode 502_4. Power supply 503 may provide an electrical signal to charged particle source 502 via any one of the illustrated connections to cause charged particle source 502 to emit primary beam of charged particles 506. In some embodiments, controller 501 may continuously monitor a signal supplied from power supply 503 to charged particle source 502. If the signal supplied from power supply 503 exceeds a threshold value, controller 501 may generate a compensated electrical signal targeting a negligible (e.g., zero or essentially zero) fluctuation in electrical signal applied to charged particle source 502. The term “essentially zero” may be understood to mean a non-zero fluctuation in an electrical signal that does not impact an emission current of an emitted primary beam of charged particles. Controller 501 may generate a compensated electrical signal (e.g., voltage or current), and may supply the compensated electrical signal back to power supply 503. Power supply 503 may then apply a bias 505 to charged particle source 502 based on the compensated electrical signal. In some embodiments, bias 505 may be applied to extractor 502_3. In some embodiments, bias 505 may be applied to anode 502_4 to adjust an accelerating voltage of charged particle source 502. Thus, FIG. 5 may illustrate a system to continuously monitor and compensate an emission current variation of charged particle beam 506 in real-time.

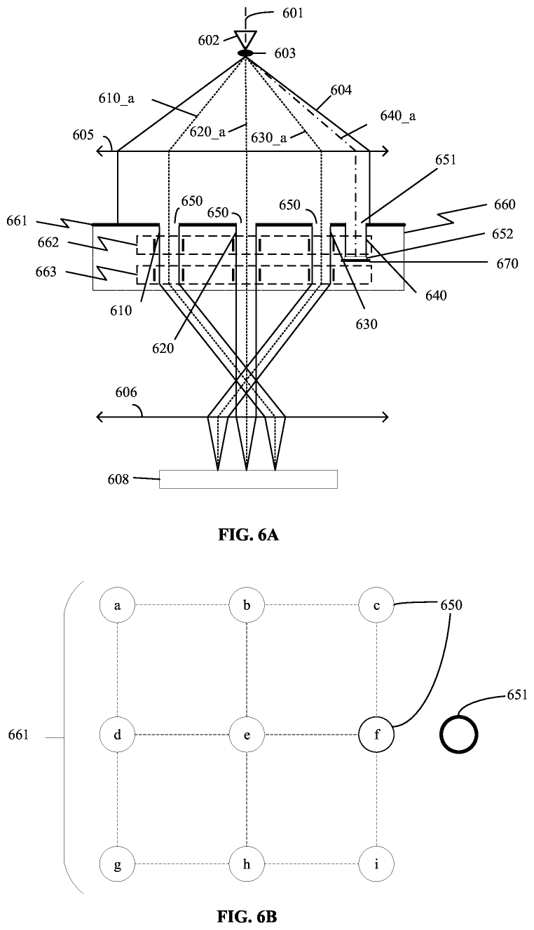

In some embodiments, a monitoring component may monitor a characteristic of a charged particle source and be positioned at a downstream location in a charged particle system. In some embodiments, a monitoring component may be an auxiliary detector to measure a characteristic or parameter of a charged particle beam. Reference is now made to FIG. 6A, which is an example schematic of charged particle apparatus 104, consistent with embodiments of the present disclosure. FIG. 6A illustrates the formation of primary electron beam 604 from electron source 602 to form a plurality of first electron beamlets 610, 620, 630 and a second electron beamlet 640. It is appreciated that primary electron beam 604 is comprised of a plurality of electrons generated by electron source 602. A source conversion unit may comprise an electron optical device 660, which may be a layered structure of optical elements that may include a micro-aperture array 661, a stigmator array 662, and a micro-deflector array 663. Electron optical device 660 may be a MEMS (microelectromechanical systems) structure. Micro-aperture array 661 may further be comprised of a plurality of first beamlet apertures 650 and a second beamlet aperture 651 to cut off some electrons in the primary electron beam emitted from electron source 602 and form first electron beamlets 610, 620, and 630 and second electron beamlet 640. Second beamlet aperture 651 may be the same or smaller in diameter than first beamlet apertures 650. In some embodiments, micro-aperture array 661 may be a separate structure from electron optical device 660 and can be referred to as an aperture substrate 661. In some embodiments, second beamlet aperture 651 may be positioned at a location on aperture substrate 661 at a radial distance further away from an optical axis 601 than a plurality of first beamlet apertures 650. Electrons in the primary electron beam emitted from electron source 602 pass through first beamlet apertures 650 to form first electron beamlets 610, 620, and 630, which then pass through electron optical device 660 towards an objective lens 606, and are focused to a focal point substantially at the surface of a sample 608. First electron beamlets 610, 620, and 630 thus irradiate the surface of sample 608 and generate corresponding secondary electron beamlets that are then captured by an electron detection device to generate one or more images of the sample. It is appreciated that the numbers of first beamlet apertures 650 is not so limited as illustrated in FIG. 6A, and that aperture substrate 661 may contain any number of first beamlet apertures 650. As illustrated in FIG. 6A, electrons in the primary electron beam emitted from electron source 602 pass through second beamlet aperture 651 to form a second electron beamlet 640. It is appreciated that FIG. 6A is an illustrative example, and the number and position of second beamlet aperture 651 on aperture substrate 661 is not so limited and will be discussed further below. It is further appreciated that first electron beamlets 610, 620, 630, and second electron beamlet 640 may be distinct and separate beamlets that share no electron beamlet in common. The dotted lines 610_a, 620_a, and 630_a and dash-dotted line 640_a in FIG. 6A serve as an illustrative guide for the pathway electrons in primary electron beam 604 that form first electron beamlets 610, 620, and 630, and second electron beamlet 640 may follow when emitted from electron source 602. In some embodiments, all first electron beamlets (such as first electron beamlets 610, 620, 630) may be focused by a single objective lens (such as objective lens 606).

Reference is now made to FIG. 6B, which shows a top-view of a surface of aperture substrate 661. In some embodiments, aperture substrate 661 may include an array of first beamlet apertures 650 as illustrated in FIG. 6B. This disclosure is not so limited and any number of first beamlet apertures 650 may be included on aperture substrate 661. For simplicity, first beamlet apertures 650 may be represented as first beamlet apertures 650a, 650b, 650c, 650d, 650e, 650f, 650g, 650h, and 650i (650a-650i). In some embodiments, aperture substrate 661 may include a second beamlet aperture 651. FIG. 6B illustrates an example configuration where second beamlet aperture 651 being positioned on aperture substrate 661 at a radial distance further away from optical axis 601 (shown in FIG. 6A) than a plurality of first beamlet apertures 650a-650i. As will be discussed further below, one or more second beamlet apertures 651 may be positioned at a location on aperture substrate 661 closer to optical axis 601 than at least one first beamlet aperture 650. Optical axis 601 is located at the center position of first beamlet aperture 650e (shown in FIG. 6B). As discussed above with respect to FIG. 6A, electrons of primary electron beam 604 that pass through the apertures on aperture substrate 661 may form a corresponding number of electron beamlets (for example, first electron beamlets 610, 620, 630, and second electron beamlet 640, shown in FIG. 6A). Thus, FIG. 6B may further illustrate a relative arrangement of the first electron beamlets and the second electron beamlet.

Referring back to FIG. 6A, second electron beamlet 640 may be used to detect parameter fluctuations of electron source 602. As discussed above, the fluctuations of an electron source may affect the stability of the primary electron beamlets hitting the surface of the sample and lead to variation of the secondary electron signal collected from the imaged surface, which ultimately affects the image quality and reproducibility of the images. Accordingly, monitoring of the electron source fluctuation is desired. In some embodiments, second electron beamlet 640 may not be focused by objective lens 606 and thus may not reach the surface of sample 608. Instead, second electron beamlet 640 may impact an auxiliary electron detector 652. As mentioned above, auxiliary electron detector 652 may be understood to be a monitoring component. Auxiliary electron detector 652 may be positioned on a supporting structure 670 between, for example, stigmator array 662 and micro-deflector array 663. Supporting structure 670 may be an additional layer of micro-apertures, stigmators, or micro-deflectors within electron optical device 660. The location of auxiliary electron detector 652 is flexible as long as the second electron beamlet 640 can be detected by auxiliary electron detector 652 before it reaches the surface of sample 608.

While not illustrated in FIG. 6A, auxiliary electron detector 652 may include circuitry configured to be communicatively coupled to an image processing system through a medium such as an electric conductor, optical fiber cable, portable storage media, IR, Bluetooth, internet, wireless network, or wireless radio. Auxiliary electron detector 652 may include circuitry configured to measure parameter fluctuations of second electron beamlet 640 that may be attributed to electron source 602 including, but not limited to, fluctuations of electron source tip current, angular distribution of electron source tip emitted-current density, virtual electron source tip position, long-term electron source tip drift, and other aberrations of electron source 602 occurring during operation. Tip current fluctuations of electron source 602 may change the amount of electrons emitted from electron source 602 and influence the number of electrons irradiating sample 608. This may create a less detectable signal and decrease the signal-to-noise ratio of a generated image. The angular distribution of tip emitted-current density is the current variation across each solid angle of primary electron beam 604. Fluctuations in the angular distribution of tip emitted-current density from electron source 602 may result in different first electron beamlets, that are formed by first beamlet apertures (650a-650i in FIG. 6B), having different currents. In SEM operation, electron source 602 may experience vibrations. These vibrations may cause fluctuations in the tip position of electron source 602. Tip position can also slowly drift over time. Such fluctuations and the tip drift may also cause fluctuations and slow changes in beamlet current. Parameter fluctuations of electron source 602 may consequently impart fluctuations to first and second electron beamlets (e.g., 610, 620, 630, and 640 in FIG. 6A) in multi-beam apparatus 104 and may distort images generated by an image processing system from captured secondary electrons collected from first electron beamlets 610, 620, 630 irradiating surface of sample 608.

Auxiliary electron detector 652 may continuously monitor second electron beamlet 640 to detect fluctuations such as those described above. Detected fluctuations in second electron beamlet 640 may be related to fluctuations in first electron beamlets 610, 620, 630 since second electron beamlet 640 and first electron beamlets 610, 620, 630 originate from the same electron source 602. Continuous monitoring of second electron beamlet 640 by auxiliary electron detector 652 may provide uninterrupted operation of imaging and fluctuation detection as second electron beamlet 640 may be active at the same time as first electron beamlets 610, 620, and 630. This may increase throughput of sample inspection and inspection image acquisition.

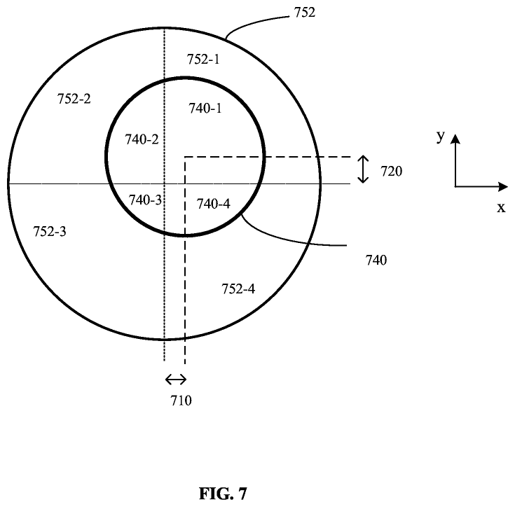

Reference is now made to FIG. 7 which shows a top-view of a surface of an example auxiliary electron detector 752 that can be used in the multi-beam electron inspection apparatus shown in FIG. 6A, consistent with embodiments of the present disclosure. In some embodiments, auxiliary electron detector 752 may include multiple detection segments that are configured to measure the intensity of electrons impacting each detection segment. For example, auxiliary electron detector 752 may comprise four quadrants 752-1, 752-2, 752-3, 752-4, as shown in FIG. 7. Parameter fluctuations of second electron beamlet 740 may be attributed to parameter fluctuations of an electron source (such as electron source 602 in FIG. 6A) since second electron beamlet 740 originates from the electron source. In some embodiments, auxiliary electron detector 752 may be pixelated to measure parameter fluctuations of second electron beamlet 740. In some embodiments, auxiliary electron detector 752 may measure relative position shift of second electron beamlet 740 impacting auxiliary electron detector 752 to ascertain electron source parameter fluctuations. For example, as shown in FIG. 7, second electron beamlet 740 may exhibit an off-axis shift when impacting auxiliary electron detector 752. Auxiliary electron detector 752 by itself or in conjunction with controller 109 may calculate the amount of the off-axis shift by measuring the impact intensity of each portion of second electron beamlet 740 in each quadrant of auxiliary electron detector 752 (740-1 in 752-1, 740-2 in 752-2, 740-3 in 752-3, and 740-4 in 752-4). For example, as shown in FIG. 7, quadrant 752-1 is impacted by the largest portion 740-1 of second electron beamlet 740, and accordingly produces the largest impact intensity output. In contrast, quadrant 752-3 is impacted by the smallest portion 740-3 of second electron beamlet 740, and accordingly produces the lowest impact intensity output. The measured intensity signals (I₇₄₀₋₁, I₇₄₀₋₂ I₇₄₀₋₃, and I₇₄₀₋₄) from quadrants 752-1, 752-2, 752-3, and 752-4 may be delivered to an image processing system where a displacement in an X-plane 710 and a displacement in a Y-plane 720 of second electron beamlet 740 may be calculated. It is appreciated that X-plane displacement 710 and Y-plane displacement 720 may be attributed as parameters of an electron source. As an example, displacement of the electron source in an X-plane 710 may be calculated by determining the ratio of second beamlet 740 intensity on a positive X-axis of auxiliary electron detector 752 to the total detected secondary electron beamlet 740 intensity. Thus, electron source parameter fluctuations may be calculated as

$$710 , Δ x = \frac{( {I}_{740 - 1} + {I}_{740 - 4} ) - ( {I}_{740 - 2} + {I}_{740 - 3} )}{( {I}_{740 - 1} + {I}_{740 - 2} + {I}_{740 - 3} + {I}_{740 - 4} )} and$$

$$720 , Δ y = \frac{( {I}_{710 - 1} + {I}_{710 - 2} ) - ( {I}_{710 - 3} + {I}_{710 - 4} )}{( {I}_{710 - 1} + {I}_{710 - 2} + {I}_{710 - 3} + {I}_{710 - 4} )} .$$

Electron source parameter fluctuations, including but not limited to fluctuations of electron source tip current, angular distribution of electron source tip emitted-current density, electron source tip position, tip region emitting electrons, long-term electron source tip drift, emission fluctuations, and other aberrations of the electron source occurring during operation, may be calculated using a similar method. Auxiliary electron detector 752 may collect and deliver the measured parameters from second electron beamlet 740 to an image processing system. Controller 109 may use measured parameter fluctuations from second electron beamlet to normalize the detected secondary electron signal from an electron detection device and may remove contributions of aberrations to generated images such as noise and long-term drift related to fluctuations of the electron source parameters. Thus, the generated images may have improved signal-to-noise ratio and enhanced quality for small-size defect detection and other metrology measurements.

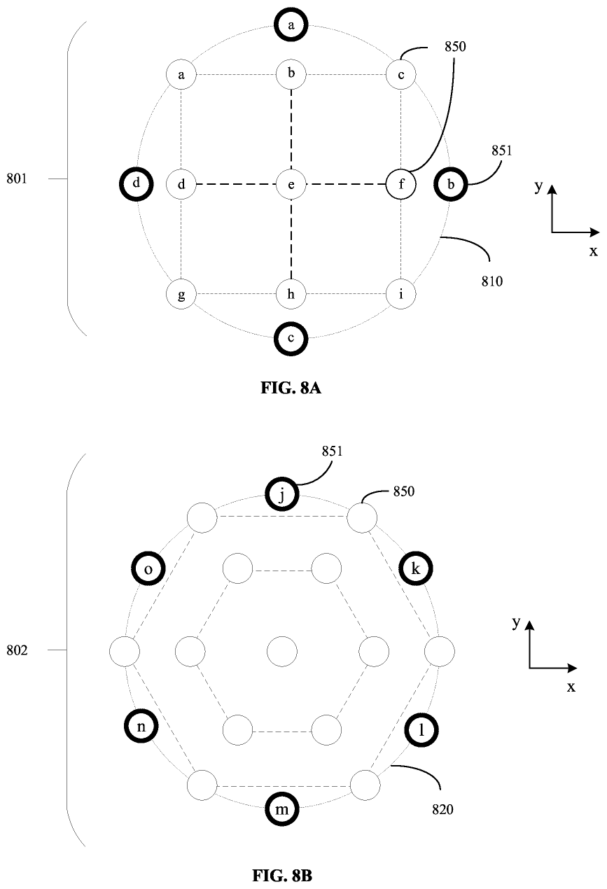

Reference is now made to FIG. 8A, which is an illustration of an example aperture substrate 801 that can be used in place of aperture substrate 661 of FIG. 6A, consistent with embodiments of the present disclosure. FIG. 8A illustrates aperture substrate 801 with a rectangular array of first beamlet apertures 850a-850i and surrounding second beamlet apertures 851a, 851b, 851c, 851d (851a-851d) at a minimum distance from an optical axis. As discussed above, a center of first electron beamlet aperture 850e may be aligned with the optical axis. The dotted circle 810 surrounding first beamlet apertures 850a-850i represents the locations at which second beamlet apertures 851a-851d may be positioned at a minimum radial distance from the optical axis while outside the first beamlet apertures. The radial distance from the optical axis to each of second beamlet apertures 851a-851d is equal to the radial distance to each corner first beamlet aperture 850a, 850c, 850g, 850i. In general, as the radial distance between first beamlet apertures 850a-850i and the optical axis (i.e., first beamlet aperture 850e) increases, the quality of formed first electron beamlets may decrease as a result of off-axis aberrations and distortions. Off-axis aberrations may distort the first electron beamlet's shape or position and may be highest for first electron beamlets at each corner (e.g., beamlets formed by first beamlet apertures 850a, 850c, 850g, or 850i). In embodiments as illustrated in FIG. 8A, second electron beamlets formed by second beamlet apertures 851a-851d may be monitored to accurately determine off-axis aberrations or distortions that may be present in first electron beamlets formed by first beamlet apertures 850a, 850c, 850g, and 850i because they are at the same radial distance from the optical axis. Since the second electron beamlets formed by second beamlet apertures 851a-851d are positioned at a same radial distance from the optical axis as the first electron beamlets formed by first beamlet apertures 850a, 850c, 850g, and 850i, off-axis aberrations monitored in the second electron beamlets will be apparent in the corresponding first electron beamlets. Moreover, since the second beamlet apertures 851a-851d are positioned at a minimum distance outside of the array of first beamlet apertures 850a-850i, off-axis aberrations monitored in the corresponding second electron beamlets may be approximated to the first electron beamlets formed by first beamlet apertures 850b, 850d, 850f, and 850h.

Monitoring more than one second electron beamlet may improve signal collection and sensitivity to electron source parameter fluctuations. For example, the multi-beam apparatus with aperture substrate 801 may include four auxiliary electron detectors (similar to auxiliary electron detector 652 in FIG. 6A) to monitor all four second electron beamlets created by second beamlet apertures 851a-851d. Furthermore, the auxiliary electron detectors may be segmented detectors as shown in FIG. 7 and may be used to measure parameter fluctuation and position offset information of the second electron beamlets. Four auxiliary electron detectors may provide a greater number of detected fluctuations in the four second electron beamlets formed by second beamlet apertures 851a-851d and thus may increase fluctuation detection sensitivity and improve overall electron detection data delivered to an image processing system.

In some embodiments, each second electron beamlet formed by second beamlet apertures 851a-851d may similarly be measured to obtain an electron source parameter fluctuation information pertaining to a positive or negative direction in X- or Y-axis. In some embodiments, a subset of second electron beamlets may be grouped to determine electron source fluctuations in a specific orientation. For example, the measurement outputs from the second electron beamlets from second beamlet apertures 851a and 851c may be considered together to determine Y-axis parameter fluctuations. Similarly, second electron beamlets from second beamlet apertures 851b and 851d may be measured and processed together to determine X-axis parameter fluctuations. Increasing the number of second beamlet apertures 851a-851d, and corresponding second electron beamlets formed by second beamlet apertures 851a-851d, may improve image quality and signal-to-noise ratio of the image generated by an inspection image processing system. In some embodiments, the second electron beamlets formed by second beamlet apertures 851a-851d may similarly be measured to determine the forementioned one or more fluctuations of the electron source as described above. In some embodiments, the auxiliary electron detectors may be configured to continuously measure one or more fluctuations of the electron source.

Reference is now made to FIG. 8B, which is an illustration of an example aperture substrate 802 that can be used in place of aperture substrate 661 of FIG. 6A, consistent with embodiments of the present disclosure. FIG. 8B illustrates a hexagonal array of first beamlet apertures 850 and second beamlet apertures 851j, 851k, 851l, 851m, 851n, 851o (851j-851o). Second beamlet apertures 851j-851o may be positioned outside the hexagonal array of first beamlet apertures 850 at a minimum radial distance from the optical axis, in which the minimum radial distance may be illustrated by the dotted circle 820 surrounding first beamlet apertures 850. In some embodiments, second electron beamlets formed by second beamlet apertures 851j-851o may be measured to obtain parameter fluctuations of first electron beamlets formed by first beamlet apertures 850 on aperture substrate 802 as described above. In some embodiments, second electron beamlets formed by second beamlet apertures 851j-851o may be measured by corresponding auxiliary electron detectors (similar to auxiliary electron detector 752 shown in FIG. 7) to determine one or more fluctuations of the electron source as described above. Unless stated otherwise, the term “auxiliary electron detector” used from this point on in this present disclosure shall be interpreted to be similar to auxiliary electron detector 752 in FIG. 7. The example of aperture substrate 802 illustrated in FIG. 8B may be used to further improve signal collection and sensitivity to electron source parameter fluctuations as described above. In some embodiments, the auxiliary electron detectors may be configured to continuously measure one or more fluctuations of the electron source.

In some embodiments, second electron beamlets formed by second beamlet apertures 851j-851o may be monitored by auxiliary electron detectors to detect parameter fluctuations in X-axis or Y-axis as described above. In some embodiments, second electron beamlets formed by second beamlet apertures 851j-851o may be monitored by corresponding auxiliary electron detectors to detect parameter fluctuations in both an X and Y-axis. For example, the measurement outputs from the second electron beamlets formed by second beamlet apertures 851l and 851o may be considered together to determine X-axis and Y-axis parameter fluctuations. In some embodiments, the auxiliary electron detectors may be configured to continuously measure one or more fluctuations of the electron source.

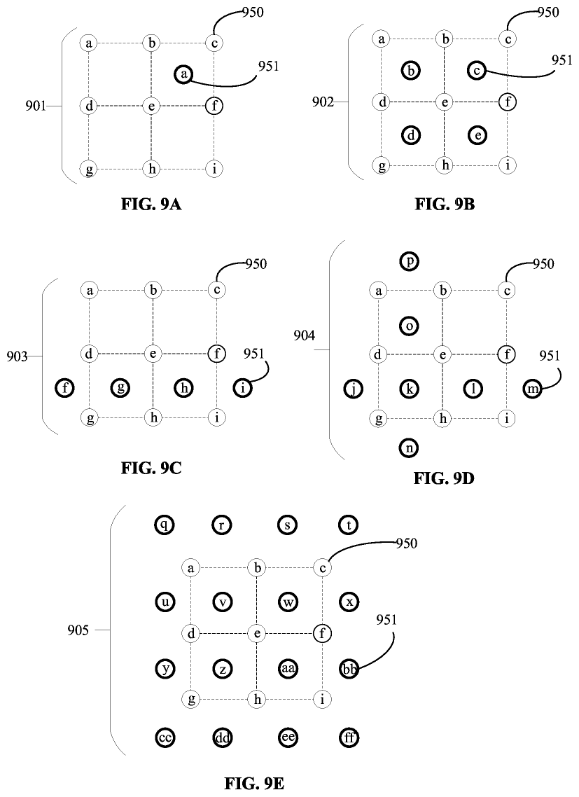

Reference is now made to FIGS. 9A-9E, in which various examples are illustrated of aperture substrates 901, 902, 903, 904, and 905 comprising a plurality of first beamlet apertures 950a-950i and one or more second beamlet apertures 951. Embodiments illustrated in FIGS. 9A-9E are schematic representations of second beamlet aperture 951 positions relative to first beamlet apertures 950a-950i on aperture substrates 901-905. It is appreciated that each aperture substrate 901-905 is not so limited and may contain any number of first beamlet apertures 950 in any arrangement. In some embodiments, second beamlet aperture 951a may be positioned between the plurality of first beamlet apertures 950a-950i. As illustrated as an example schematic in FIG. 9A, second beamlet aperture 951a may be positioned between four first beamlet apertures 950b, 950c, 950e, 950f on aperture substrate 901. In some embodiments, second beamlet aperture 951a may be positioned between other groups of, for example, four first beamlet apertures. Correspondingly, second beamlet aperture 951a may be positioned at a closer radial distance relative to the optical axis, and the quality of the second electron beamlet formed by second beamlet aperture 951a (e.g., minimized off-axis aberrations, minimized beam shift) may be improved. The second electron beamlet formed by second beamlet aperture 951a may be continuously monitored by corresponding auxiliary electron detector and measure one or more fluctuations of the electron source as described above with improved sensitivity and accuracy.

Reference is now made to FIG. 9B. In some embodiments, a plurality of second beamlet apertures 951 may be interspersed between the plurality of first beamlet apertures 950a-950i. As illustrated as an example schematic in FIG. 9B, second beamlet apertures 951b, 951c, 951d, and 951e (951b-951e) may be positioned closer to the optical axis (i.e., center of first beamlet aperture 950e) compared to each off-axis first beamlet aperture 950a, 950b, 950c, 950d, 950f, 950g, 950h, and 950i. An increased number of second beamlet apertures 951b-951e may improve the quality of second electron beamlets formed by second beamlet apertures 951b-951e as described above. Furthermore, an increased number of second beamlet apertures interspersed between the first beamlet apertures 950a-950e may further improve the quality of second electron beamlets formed by second beamlet apertures 951b-951e as described above. Corresponding auxiliary electron detectors may monitor the second electron beamlets formed by second beamlet apertures 951b-951e to measure the forementioned one or more fluctuations of the electron source. Furthermore, the corresponding auxiliary electron detectors to second beamlet apertures 951b-951e may measure emission fluctuation that can be attributed to the first electron beamlet formed by first beamlet aperture 950e. Emission fluctuation is the fluctuation of emission current in each beamlet formed from aperture substrate 902, or other aperture substrates consistent with embodiments of this present disclosure. The detection data from the auxiliary electron detectors may be used to extrapolate emission fluctuation of the first electron beamlet formed by first beamlet aperture 950e because the second electron beamlets formed by second beamlet apertures 951b-951e surround the first electron beamlet formed by first beamlet aperture 950e. In some embodiments, the auxiliary electron detectors may be configured to continuously measure one or more fluctuations of the electron source.

Reference is now made to FIG. 9C. In some embodiments, a plurality of second beamlet apertures 951 may be positioned along an X or Y axis throughout a plurality of first beamlet apertures 950. As illustrated as an example schematic in FIG. 9C, second beamlet apertures 951f, 951g, 951h, and 951i (951f-951i) may be positioned along an X-axis throughout a plurality of first beamlet apertures 950a-950i. Second electron beamlets formed by second beamlet apertures 951f-951i may be monitored to detect the forementioned one or more fluctuations in an electron source along an X-axis as described above. In some embodiments, while not illustrated in FIG. 9C, second beamlet apertures 951f-951i may be arranged along a Y-axis throughout the plurality of first beamlet apertures 950a-950i. Second electron beamlets formed by second beamlet apertures arranged along a Y-axis may be monitored to detect the forementioned one or more fluctuations in an electron source along a Y-axis. In the example illustrated in FIG. 9C, second electron beamlets formed by second beamlet apertures 951f-951i arranged along either an X or Y axis may be monitored by corresponding auxiliary electron detectors to detect fluctuations of the angular distribution of current density emitted from the electron source tip. In the example illustrated in FIG. 9C, two second beamlet apertures (e.g., 951f and 951g) have different radial distances from the optical axis (i.e., center of first beamlet aperture 950e) so two second electron beamlets that are formed by second beamlet apertures 951f-951i will contain information about the angular distribution of emitted current density from the electron source tip. Second electron beamlets formed by second beamlet apertures 951f-951i may be monitored by corresponding auxiliary electron detectors to determine the forementioned one or more fluctuations of an electron source with improved accuracy and sensitivity. In some embodiments, the auxiliary electron detectors may be configured to continuously measure one or more fluctuations of the electron source.

Reference is now made to FIG. 9D. In some embodiments, second beamlet apertures 951 may be arranged along both an X and Y-axis throughout a plurality a first beamlet apertures 950a-950i. As illustrated as an example schematic in FIG. 9D, at least two second beamlet apertures 951j, 951k, 951l, 951m, 951n, 951o, and 951p (951j-951p) arranged along both X and Y axis have different radial distances from the optical axis (i.e., center of first beamlet aperture 950e). At least two second electron beamlets that are formed by second beamlet apertures 951j-951p will contain more information about the angular distribution of emitted current density from the electron source tip compared to the example illustrated in FIG. 9C. Therefore, second electron beamlets formed by second beamlet apertures 951j-951p may be monitored by corresponding auxiliary electron detectors to determine the forementioned one or more fluctuations of an electron source with improved accuracy and sensitivity. In some embodiments, the auxiliary electron detectors may be configured to continuously measure one or more fluctuations of the electron source.

Reference is now made to FIG. 9E. In some embodiments, second beamlet apertures 951 may be dispersed throughout and surround a plurality of first beamlet apertures 950a-950i. As illustrated in FIG. 9E, second beamlet apertures 951q, 951r, 951s, 951t, 951u, 951v, 951w, 951x, 951y, 951z, 951aa, 951bb, 951cc, 951cc, 951dd, 951ee, and 951ff (951q-951ff) may be positioned throughout and surround first beamlet apertures 950a-950i. Further illustrated in FIG. 9E, first beamlet apertures 950a-950i may each be surrounded by, for example, four of second beamlet apertures 951q-951ff. For example, first beamlet aperture 950a may be surrounded by second beamlet apertures 951q, 951r, 951u, and 951v. In such an example, second electron beamlets formed by second beamlet apertures 951q, 951r, 951u, and 951v may be detected by corresponding auxiliary electron detectors which measure emission fluctuations of the corresponding second electron beamlets. The detection data from the auxiliary electron detectors may be used to extrapolate emission fluctuation of the first electron beamlet formed by first beamlet aperture 950a because the second electron beamlets are good representatives of the corresponding first electron beamlet as they are surrounding and close to the first beamlet. Similarly, first beamlet aperture 950b can be paired with second beamlet apertures 951r, 951s, 951v, and 951w. In some embodiments, the detection data from the auxiliary electron detectors may be used to determine one or more fluctuations of the electron source as described above with improved sensitivity and accuracy. In some embodiments, the auxiliary electron detectors may be configured to continuously measure one or more fluctuations of the electron source.

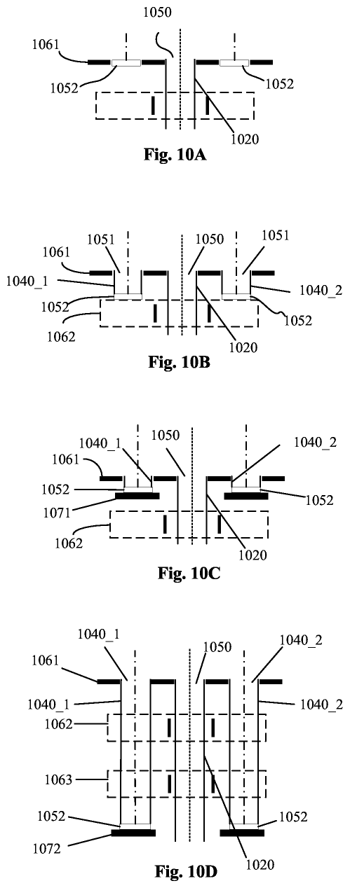

Reference is now made to FIGS. 10A-10D, which are example illustrations showing various locations of one or more auxiliary detectors, consistent with embodiments of the present disclosure. As illustrated in FIG. 10A, one or more auxiliary electron detectors 1052 may be placed on aperture substrate 1061, and level or flush with the opening of second beamlet apertures 1051. In this example, just as the electrons from the primary electron beam (such as primary electron beam 604 in FIG. 6A) pass through second beamlet apertures 1051 to form second electron beamlets the second electron beamlets may impact auxiliary electron detectors 1052. To increase detection sensitivity, in some embodiments, the auxiliary electron detectors may be placed below aperture substrate 1061.

As illustrated in FIG. 10B, one or more auxiliary electron detectors 1052 may be positioned on top of stigmator array 1062. Second electron beamlets 1040_1 and 1040_2 may be formed by second beamlet apertures 1051 and then impact auxiliary electron detectors 1052. Although not illustrated in FIG. 10B, it is appreciated that auxiliary electron detectors 1052 may be positioned on top of a micro-deflector array (such as micro-deflector array 663 shown in FIG. 6A) instead of stigmator array 1062 as illustrated in FIG. 10B.

FIG. 10C illustrates an example where one or more auxiliary electron detectors 1052 may be positioned on a supporting structure 1071 located between aperture substrate 1061 and stigmator array 1062. Supporting structure 1071 may be an additional layer of micro-apertures, stigmators, or micro-deflectors within an electron optical device (such as electron optical device 660 shown in FIG. 6A). FIG. 10D illustrates an example where one or more auxiliary electron detectors 1052 may be positioned on a supporting structure 1072 located below the electron optical device (such as electron optical device 660 shown in FIG. 6A) and above an objective lens (such as objective lens 606 shown in FIG. 6A). Second electron beamlets 1040_1 and 1040_2 may pass through the electron optical device and impact one or more auxiliary electron detectors 1052 to generate a signal. Supporting structure 1072 may be an additional aperture array, beam separator, deflection scanning unit, or any other optical element positioned below (i.e., down-beam) the electron optical device and positioned above (i.e., up-beam) the objective lens in apparatus 104. It is appreciated that second electron beamlets 1040_1 and 1040_2 in these embodiments may not be deflected by a micro-deflector array (such as micro-deflector array 663 in FIG. 6A) to impact auxiliary electron detectors 1052. In each example illustrated in FIGS. 10A, 10B, 10C, and 10D, first electron beamlet 1020, as an example, formed by first beamlet aperture 1050, passes through the electron optical device and may be focused by the objective lens to irradiate the surface of a sample (such as sample 608 in FIG. 6A).

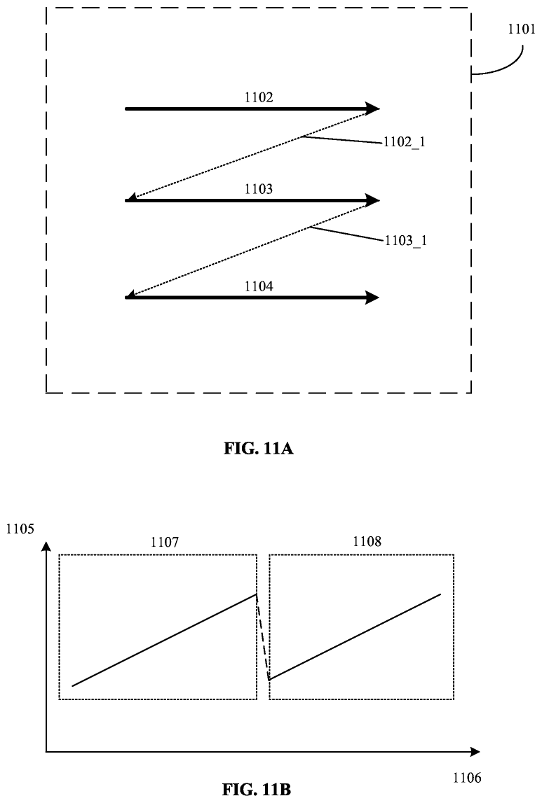

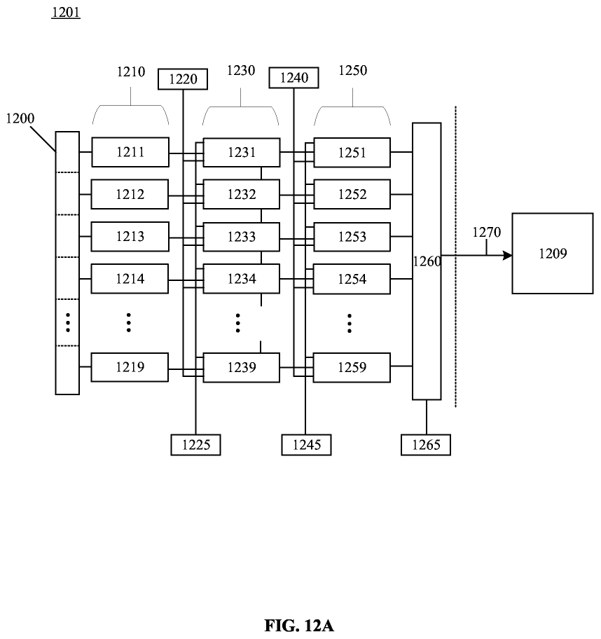

Reference is now made to FIG. 11A, which is a schematic diagram illustrating various scan lines of an electron beam across a sample surface applied by a charged particle beam apparatus (such as the charged particle beam apparatus shown in FIG. 2 or FIG. 3), consistent with embodiments of this present disclosure. FIG. 11A illustrates a top-view field of view 1101 of a sample, in which an electron beam is scanned across field of view 1101 as a scan line for a time interval. Deflectors (e.g., deflectors 233 in FIG. 2 or deflection scanning unit 326 in FIG. 3) may deflect the focused primary electron beam. It is appreciated that “field of view” may be understood to mean an area of a sample to be imaged. A field of view may be any size appropriate to image an area of a sample. In some embodiments, field of view 1101 may be 8000 by 8000 pixels. In some embodiments, field of view 1101 may be any number of pixels appropriate to image an area of a sample. Field of view 1101 may include an area of interest of a sample. It is appreciated that FIG. 11A is for illustrative purposes and the width, length, and number of scan lines 1102, 1103, and 1104 are not so limited. After first scan line 1102 is completed, the electron beam may be repositioned to a different location as illustrated by trace line 1102_1, where the electron beam may then be rescanned across the sample as shown by scan line 1103. Similarly, the electron beam may be repositioned and scanned a third time as shown by scan line 1103_1. During each scan, secondary electrons are emitted and collected by a corresponding detector to generate a corresponding image for the sample scanned throughout field of view 1101. In some embodiments, secondary electrons emitted and collected by the detector may be used to generate an image for each scan line.

Reference is now made to FIG. 11B, which is an example illustration of an electrical signal applied to a charged particle beam deflector over time on a sample. FIG. 11B illustrates a voltage 1105 applied to a deflector (e.g., deflectors 233 in FIG. 2 or deflection scanning unit 326 in FIG. 3) to deflect an electron beam over time 1106. Traditionally, a voltage is applied at a constant rate to a deflector to deflect (e.g., scan) an electron beam across the surface of a sample at a constant speed. Voltage region 1107 may correspond to a first scan of an electron beam across a sample (e.g., first scan line 1102 in FIG. 11A), and voltage region 1108 may correspond to a second scan of an electron beam across a sample (e.g., second scan line 1103 in FIG. 11A).

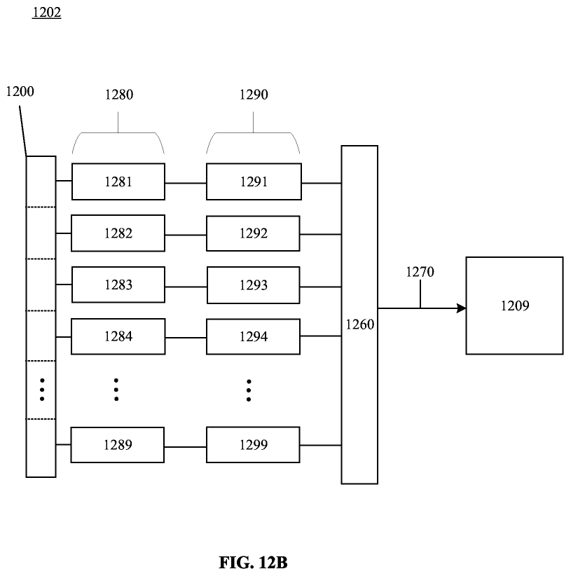

In some embodiments, an event-based detection system is used to count a number of electrons impacting a detector within a period of time with a location on a sample. The event-based detection system may facilitate back-calculating a compensation signal to reconstruct an image of a sample. The image of the sample may contain imperfections as a result of a deviation in a primary electron beam emission current, and the reconstructed image may correct the imperfections. In some embodiments, the reconstructed image may exhibit compensated brightness, contrast, focus, or other image characteristics. Reference is now made to FIG. 12A, which illustrates a schematic representation of an exemplary architecture of a detection system 1201, consistent with embodiments of the present disclosure. The detection system may be provided with a detector (e.g., detector 244 in FIG. 2 or detector 344 in FIG. 3) including an array of sensing elements. As seen in cross section, detector 1200 may have a structure resembling a back-side illumination CMOS image sensor. Electrons may be incident on an exposed (incidence) surface side of detector 1200. At the back side, there may be a P+ layer that may serve as the anode of a diode included in a sensing element array. The anode may be negatively biased by a voltage source with zero sourcing impedance. When, for example, an electron with about 9 keV of kinetic energy penetrates a sensing element of detector 1200, the event may excite about 2,000 electron-hole pairs in a depletion zone of the sensing element. The electrons of those pairs may be collected at the cathode of the sensing element and may contribute to a detection signal. For example, current pulses may be generated with magnitudes substantially proportional to kinetic energy of the incident electrons.

Raw detection signal from sensing elements in the form of sharp current pulses may be fed into an electronic circuit. For example, there may be provided front-end electronics 1210. Front-end electronics 1210 may include individual circuits 1211, 1212, 1213, 1214, and so on, for example up to an nth circuit 1219. Each of the individual circuits of front-end electronics 1210 may correspond to one sensing element of the array of detector 1200. Each individual circuit of front-end electronics 1210 may include a current buffer and an amplifier, such as a transimpedance amplifier, a charge amplifier, or a charge transfer amplifier.

In some embodiments, components may be integrated with detector 1200. Detector 1200 may be provided as a semiconductor substrate including an array of sensing elements. The array of sensing elements may include a diode. A low-gain amplifier may be built up in the back side of a semiconductor substrate that includes the PIN diode. The amplifier may be configured to operate in a linear mode and may avoid a region where the amplifier may exhibit recovery time. The semiconductor substrate may include a plurality of segmented diodes. A plurality of amplifiers may be configured such that a respective amplifier of the plurality of amplifiers is attached to each of the diodes.

In some embodiments, an array of sensing elements may be constructed with Low Gain Avalanche diode (LGAD) segments. LGAD may provide relatively small current gain, for example around 10× to about 20×, operating very fast while remaining in a linear mode, unlike conventional avalanche diodes that may go into avalanche current flow following a triggering event and require a mechanism to reset the current flow to be ready for the next triggering event for detection. Supplying extra current gain of an LGAD may be helpful for precise detection timing or simplifying front-end electronics 1210. LGAD may not require bias current. Furthermore, LGAD may be helpful to reduce power consumption of a detection system.

After amplification, signal output from each of the individual circuits of front-end electronics 1210 may be fed into event detector 1230. Event detector 1230 may include individual circuits 1231, 1232, 1233, 1234, and so on, for example up to an nth circuit 1239. Each of the individual circuits of event detector 1230 may correspond to one sensing element of the array of detector 1200. Each individual circuit of event detector 1230 may include a discriminator, a discriminator block, a pulse height analyzer, or the like. Event detector 1230 may be useful in counting electrons that impact detector 1200.

Returning to FIG. 12A, event detector 1230 may include discriminator blocks. The discriminator blocks may include logical operation processing that may be implemented using hardware such as an electronic circuit. The discriminator block may compare an incoming signal, e.g., event signal, against a reference level and output a signal such as a detection pulse or an event detection flag when a rising edge or a falling edge of the incoming signal crosses the reference level. For example, a measured current signal may be compared to a threshold, Thₑ. Threshold Thₑ may be set sufficiently higher than a background noise level. In some embodiments, discriminator blocks may be implemented by a controller. In some embodiments, a discriminator block may be a constant fraction discriminator. Event detector 1230 may also include other types of circuitries, such as a comparator configured to compare incoming voltages, current, or other types of signals, to a reference level.

The detection system of FIG. 12A may also include a pixel count buffer 1250. Pixel count buffer 1250 may include individual circuits 1251, 1252, 1253, 1254, and so on, for example up to an nth circuit 1259. Each of the individual circuits of pixel count buffer 1250 may correspond to one sensing element of the array of detector 1200. Output from each of the circuits of event detector 1230 may be fed into a respective circuit of pixel count buffer 1250.

The detection system of FIG. 12A may also include a count summing unit 1260. Output from each of the circuits of pixel count buffer 1250 may be fed into count summing unit 1260. Counts of received electrons from each of the sensing elements in detector 1200 may be combined to, for example, obtain a gray level of an image to be used in image processing. Combining counts of received electrons may comprise summing counts across multiple sensing elements, multiple sampling time periods, or multiple frames. Data from sensing elements may be combined based on properties of charged particle arrival events. For example, data from sensing elements may be combined on the basis of a charged particle arrival event's time stamp, sensing element location, scan action of a primary beam of a charged particle beam apparatus, or properties of the charged particle beam apparatus. Combined data may be used for reconstructing an image of a sample. For example, a pixel count sum 1270 may be fed into an image processing system 1209 (e.g., image processing system 290 in FIG. 2 or image processing system 390 in FIG. 3). Count summing unit 1260 may include logical operation processing that may be implemented using hardware such as an electronic circuit, or, for example, by a controller.

There may be provided various signal lines, and so on, connecting various elements in the detection system of FIG. 12A. For example, there may be a pixel clock 1220 connected to each of the individual circuits of event detector 1230. Furthermore, a detection control 1225 may be connected to each of the individual circuits of event detector 1230. Similarly, there may be another pixel clock 1240 connected to each of the individual circuits of pixel count buffer 1250. Furthermore, a detection control 1245 may be connected to each of the individual circuits of pixel count buffer 1250. Also, a delayed pixel clock 1265 may be connected to count summing unit 1260. Pixel clocks 1220, 1240, and 1265 may run at the same or different speeds.

The detection system of FIG. 12A may use relatively simplified electronic components and may achieve higher speed while enabling good packaging flexibility. For example, components may be integrated on a semiconductor chip. Front-end electronics 1210, event detector 1230, pixel count buffer 1250, or count summing unit 1260 may be provided in a semiconductor package, such as a single monolithic semiconductor chip. For example, front-end electronics 1210, event detector 1230, pixel count buffer 1250, and count summing unit 1260 may be provided as layers in a semiconductor chip that may be connected to detector 1200, and to an image processing system 1209 (e.g., image processing system 290 in FIG. 2 or image processing system 390 in FIG. 3). The dashed line shown between image processing system 1209 and count summing unit 1260 in FIG. 12A may represent a division between on-chip structure and off-chip structure. In some embodiments, front-end electronics 1210, event detector 1230, pixel count buffer 1250, and count summing unit 1260 may be provided as separate modules.

Counting electrons may have numerous advantages as compared to detecting an analog signal. A semiconductor chip including a detector and detection system, for example as discussed in embodiments herein, may achieve higher speed and may avoid processing bottlenecks. For example, overlap of signal pulses in adjacent electron arrival events may impede detection accuracy. Therefore, it may be important for a detector to have high speed. In some devices, front-end electronics may impose a limit on bandwidth. However, as discussed with respect to embodiments herein, when front-end electronics or other components are integrated in a semiconductor chip, higher speed may be achieved. In some embodiments, components configured to count a number of charged particles, such as by providing output in the form of an event flag, may be relatively simple and may allow system simplification, and high speed. Rather than sampling an analog signal to represent beam intensity, it may be advantageous to detect individual events and count the number of individual events occurring over a time period.

Counting electrons may be particularly effective in some types of applications, such as CD-SEM, high-resolution high-throughput inspection, or metrology of manufactured semiconductor devices. In some embodiments discussed herein, a detection system may enable electron counting for electron beams of, for example, 100 pA and lower.

Reference is now made to FIG. 12B, which illustrates a schematic representation of another exemplary architecture of a detection system, consistent with embodiments of the present disclosure. A detection system 1202 of FIG. 12B may be similar to detection system 1201 of FIG. 12A except that detection system 1202 provides an energy storage device 1280 that is connected to detector 1200 including an array of sensing elements, among other differences. Energy storage device 1280 may include individual energy storage units 1281, 1282, 1283, 1284, and so on, for example up to an nth energy storage unit 1289. Each of the individual energy storage units may correspond to one sensing element of the array of detector 1200. Energy storage units 1281 to 1289 may be configured to accumulate energy in response to an output signal from respective sensing elements of the array of sensing elements of detector 1200 being fed thereto. Each energy storage unit may include a micro-capacitor, for example.

Raw detection signal from sensing elements may be fed into energy storage units. Energy accumulated in the energy storage units may be stored until the energy storage units are reset. For example, when the energy storage device 1280 includes a capacitor, energy level may be reset when the capacitor is discharged. While energy is being fed into energy storage device 1280, the stored energy level may be read. Energy level may be maintained for a duration until reset.

In some embodiments, energy associated with sensing element output may be reset by an active reset or a passive reset. An active reset may include affirmatively causing an element to reduce its energy level. For example, the active reset may include discharging a capacitor. A passive reset may include passively allowing the energy level to be reduced. For example, in some devices, the energy level may decay over time. In a sensing element itself, the energy generated in response to an electron arrival event may be dissipated as time passes. In some embodiments, a current pulse generated by a single electron arrival event at a PIN detector may have a pulse width of, for example, 3 to 5 ns, and thus, sensing elements may be passively reset after about 3 to 5 ns.

In some embodiments, energy storage device 1280 may be omitted. For example, sensing elements themselves may function as energy collection units and may inherently reset periodically as surges of electron-hole pairs generated in response to electron arrival events gradually dissipate.

Detection system 1202 may also include a detection circuit array 1290. Detection circuit array 1290 may include individual circuits 1291, 1292, 1293, 1294, and so on, for example up to an nth circuit 1299. Each of the individual circuits of detection circuit array 1290 may correspond to one sensing element of the array of detector 1200. Each individual circuit of detection circuit array 1290 may include an event pulse detector. An event pulse detector may be configured to detect an arrival event of a charged particle on a sensing element. For example, an event pulse detector may be configured to detect a charged particle arrival event by detecting an amount of energy in a sensing element and may be configured to increment a counter thereby indicating that a charged particle has been counted. In some embodiments, other ways to detect output signal from a sensing element may be used. For example, output from a sensing element may be read by being sampled at a predetermined time. Detection circuit array 1290 may include a clock. In some embodiments, a global clock may be provided. Using a global clock, operations of sensing elements and their associated circuitry may be synchronized. In some embodiments, individual sensing elements and their associated circuitry may have their own clocks.

A circuit of an event pulse detector may include comparators. In addition, various other circuit components may be provided, such as voltage references. In some embodiments, energy captured in energy storage units may exceed an overflow limit, and counting of charged particles may be impeded. For example, a miscount may occur when more than one charged particle is received in a sensing element and the received energy may not be indicative of the total number of charged particles received. Energy accumulated in an energy storage unit may remain the same even after subsequent charged particles are received. Thus, it may be beneficial to provide circuitry for processing data of sensing elements on a timewise basis. Detection circuit array 1290 may include a storage for storing sensing element data that may be associated with a time stamp.

Detection system 1202 may also include a count summing unit 1260. Output from each of the circuits of detection circuit array 1290 may be fed into count summing unit 1260. Counts of received charged particles from each of the sensing elements in detector 1200 may be summed to obtain a gray level of an image to be used in image processing. For example, a pixel count sum 1270 may be fed into image processing system 1209. Count summing unit 1260 may include logical operation processing that may be implemented using hardware such as an electronic circuit, or, for example, by a controller.

There may be provided various signal lines, and so on, connecting various elements in detection system 1202. Detection system 1202 may include further components, such as amplifiers, signal processing circuitry, and others, for example. It will be understood that various connections and other elements, such as that shown in FIG. 12A, may be added to detection system 1202.

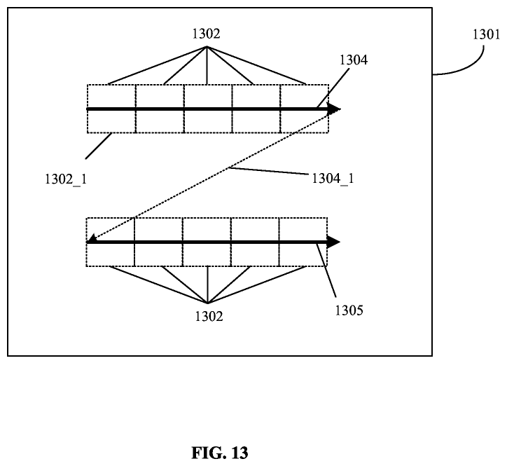

Reference is now made to FIG. 13, which is an example illustration of an example schematic of a field of view with a pixel associated with an electron landing event and timestamp, consistent with embodiments of the present disclosure. FIG. 13 illustrates a field of view 1301 of a sample which may be imaged. To collect an image of field of view 1301, an electron beam is scanned across field of view 1301 as a scan line for a time interval, as described above in FIG. 11A. Deflectors (e.g., deflectors 233 in FIG. 2 or deflection scanning unit 326 in FIG. 3) may deflect the focused primary electron beam across a surface of the sample in field of view 1301. Before an electron beam is scanned across the sample, a pixel with a size may be assigned to an area within field of view 1301. An electrical signal is applied to a charged-particle beam apparatus at a rate based on the size of the pixels. In some embodiments, the charged-particle beam apparatus is a single-beam tool (e.g., FIG. 2) or a multi-beam tool (e.g., FIG. 3). In some embodiments, the electrical signal is applied to a deflector (e.g., deflectors 233 of FIG. 2 or deflection scanning unit 326 of FIG. 3) of the charged-particle beam apparatus. The charged-particle beam may be scanned across the sample as illustrated by scan line 1304 via an applied electrical signal rate to a deflector. After scan line 1304 is completed, the charged particle beam may be repositioned to the second area as illustrated by trace line 1304_1. The charged particle beam may then be rescanned across the second area as shown by scan line 1305. As the charged particle beam is scanned across the sample, secondary charged particles (e.g., secondary electrons) may be emitted from the sample and collected by a detector (e.g., detector 244 in FIG. 2, detector 344 in FIG. 3, or detector 1200 in FIGS. 12A and 12B). For example, as the charged particle beam scans across a pixel 1302_1 via scan line 1304, a number of secondary charged particles may be emitted from the sample. A detector may collect emitted secondary charged particles and associate collected particles with a location on a sample and a timestamp. A timestamp may represent a time point when a landing event occurs for a secondary charged particle onto a detector. For example, the detector may determine a timestamp for a secondary charged particle that is collected from a location within pixel 1302_1. In some embodiments, the detector may determine a number of secondary charged particles that are collected during a time period to collect an image pixel. In some embodiments, the detector may determine a characteristic of the secondary charged particles or a characteristic of the primary beam of charged particles. In some embodiments, the detector may determine a charge on the surface of the sample associated with a pixel (e.g., pixel 1302_1), a landing location of charged particles impacting the sample, an emission characteristic of the primary charged particle beam, an injection angle, and emission angle of the secondary charged particles, or other information relevant to a sample property or operation status of a charged particle system (e.g., SEM). As a non-limiting example, a detector (e.g., detector 244 in FIG. 2, detector 344 in FIG. 3, or detector 1200 in FIGS. 12A and 12B) may calculate a charge located on the surface of the sample associated with a pixel (e.g., pixel 1302_1) by compiling all the secondary charged particles with measured timestamps that were collected from all locations within the pixel. The calculated charge may be correlated to an emission current of the primary beam impacting the sample. In some embodiments, the calculated charge may be used to normalize a deviation or variation of an actual emission current of the primary beam impacting the sample.

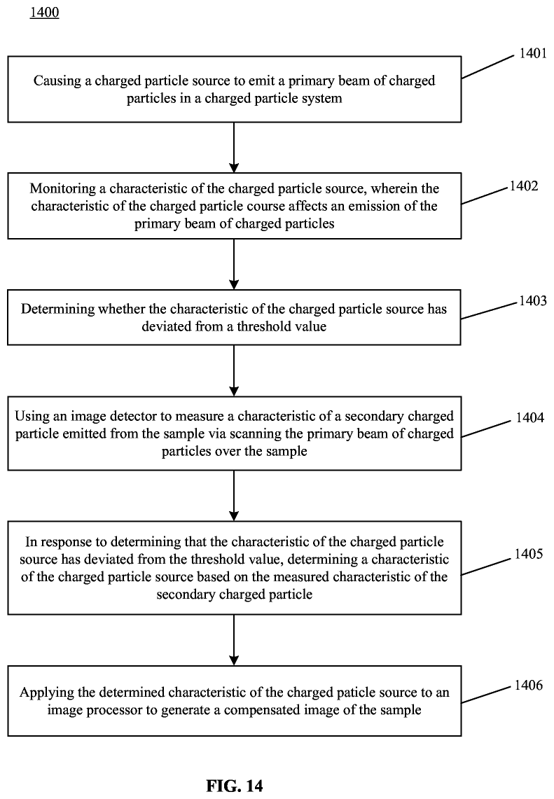

Reference is now made to FIG. 14, which is a flowchart representing an example process for compensating electron beam variations in generating a SEM image, consistent with embodiments of the present disclosure. The steps of method 1400 may be performed by an apparatus with a single-beam (e.g., FIG. 2) or a multi-beam column structure, for example, shown in FIG. 3, executing on or otherwise using the features of a computing device (e.g., controller 109 of FIG. 1). It is appreciated that the illustrated method 1400 may be altered to modify the order of steps and to include additional steps. The steps of method 1400 may be applicable to any of the embodiments as described above and illustrated in the preceding figures.

In step 1401, a primary electron beam is emitted from the electron source. The primary electron beam may be comprised of any number of electrons.

In step 1402, a characteristic of the primary electron beam is monitored. The characteristic of the primary beam may be an emission current value. In some embodiments, the characteristic of the primary beam is monitored at the electron source using a monitoring component (e.g., monitoring component 401 of FIG. 4). In some embodiments, the characteristic of the primary beam is monitored at a location downstream of an electron source. In some embodiments, the characteristic of the primary beam may be monitored by an auxiliary detector (e.g., auxiliary detector 652 of FIG. 6A, auxiliary detector 752 of FIG. 7, or auxiliary detector 1052 of FIGS. 10A-10D).

In step 1403, a deviation from a threshold value for the characteristic of the primary beam is determined. A threshold value may be determined based on a percentage of a target characteristic of the primary beam. As a non-limiting example, a target characteristic of the primary beam may be a emission current of 1 nA. The threshold value may be determined to be a 10% difference from the target emission current of 1 nA.

In step 1404, an image detector measures a characteristic of a secondary charged particle emitted from the sample via scanning the primary charged particle beam over the sample. In some embodiments, the characteristic of the secondary charged particle beam is a landing event of the secondary charged particle onto the detector. In some embodiments, the detector may measure a timestamp of the landing event and measure a number of secondary charged particles that impact the detector within a time period of collecting an image pixel.

In step 1405, a characteristic of the charged particle source is calculated based on the measured characteristic of the secondary charged particle in response to determining whether the measured characteristic of the charged particle source has deviated outside the threshold value. In some embodiments, the calculated characteristic of the charged particle source may compensate for the deviated characteristic of the charged particle source. In some embodiments, the calculated characteristic of the charged particle source may be a current on the surface of the sample, and may be derived from the measured characteristic of the secondary charged particle (e.g., in step 1404). In some embodiments, the calculated characteristic may be a charge on the surface of the sample.

In step 1406, the calculated characteristic is applied to an image processor to generate a compensated image of the sample. The image processor (e.g., image processing system 290 of FIG. 2, image processing system 390 of FIG. 3, or image processing system 1209 of FIGS. 12A and 12B) may normalize detection data during imaging and compensate for deviations from the charged particle source. In some embodiments, the compensated image may have improved image quality. In some embodiments, the compensated image may have improved signal-to-noise ratio. In some embodiments, the compensated image may have improved brightness, improved contrast, improved focus, or other improved image characteristics. The compensated image may be used to improve defect inspection or metrology measurements of the sample.

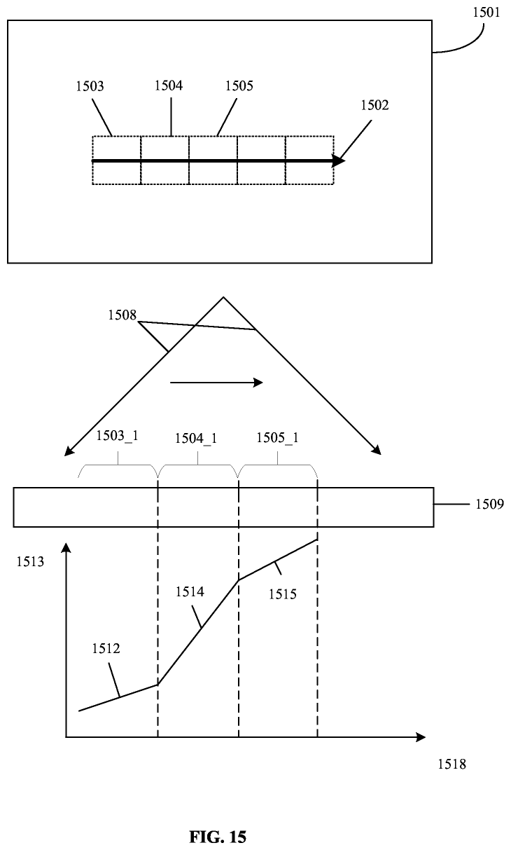

Reference is now made to FIG. 15, which is an example illustration of dynamically adjusting scanning of a primary beam of charged particles across a sample to compensate for a variation in a charged particle source, consistent with embodiments of the present disclosure. FIG. 15 illustrates a top-view field of view 1501 of a sample which may be imaged. To collect an image of field of view 1501, an electron beam is scanned across field of view 1501 as a scan line 1502 for a time interval. As described above, deflectors (e.g., deflectors 233 in FIG. 2 or deflection scanning unit 326 in FIG. 3) may deflect the focused primary electron beam across a surface of the sample in field of view 1501. Before an electron beam is scanned across the sample, a pixel with a size may be assigned to an area within field of view 1501. An electrical signal is applied to a charged-particle beam apparatus at a rate based on the size of the pixels. The charged-particle beam may be scanned across the sample as illustrated by scan line 1502 via an applied electrical signal rate to a deflector and may pass through assigned areas 1503, 1504, and 1505. Assigned areas 1503, 1504, and 1505 may be referred to as pixel 1503, pixel 1504, and pixel 1505. As the primary beam scans across pixels 1503-1505, any deviation of the charged particle source may impact a dose of charged particles impacting each area of the sample. This may decrease image quality generated from field of view 1501. In some embodiments, a rate of electrical signal applied to a deflector may be dynamically adjusted to maintain a constant dose of charged particles impacting each area of the sample. A charged particle beam 1508 is illustrated in FIG. 15 as being deflected from left to right across a surface of a sample 1509 for a period of time 1518. Brackets 1503_1, 1504_1, and 1505_1 represent pixels 1503, 1504, and 1505 (e.g., the areas scanned on sample 1509). Bracket 1503_1 corresponds to a first rate 1512 of an electrical signal 1513 applied to a deflector of a charged particle beam apparatus to scan across pixel 1503. Bracket 1504_1 corresponds to a second rate 1514 of electrical signal 813 applied to the deflector to scan across pixel 1504 and bracket 1505_1 corresponds to a third rate 1515 of electrical signal 1513 applied to the deflector to scan the charged particle beam across pixel 1505. A larger rate (e.g., slope) of electrical signal applied to the deflector may indicate a faster scan across the sample, and lower rate of electrical signal applied to the deflector may indicate a slower scan across the sample. Since bracket 1504_1 is associated with a larger rate of signal applied (e.g., second rate 1514), this may cause the charged-particle beam to scan more quickly across pixel 1504 compared to pixel 1503 and pixel 1505. In some embodiments, this may be applied if a deviation in the charged particle source causes an increase in emission current while scanning across pixel 1504. Thus, a faster scan relative to pixel 1503 and pixel 1505 may normalize the dose of charged particles impacting each area of sample 1509. Therefore, a compensate image may be generated with improved image quality as described above.

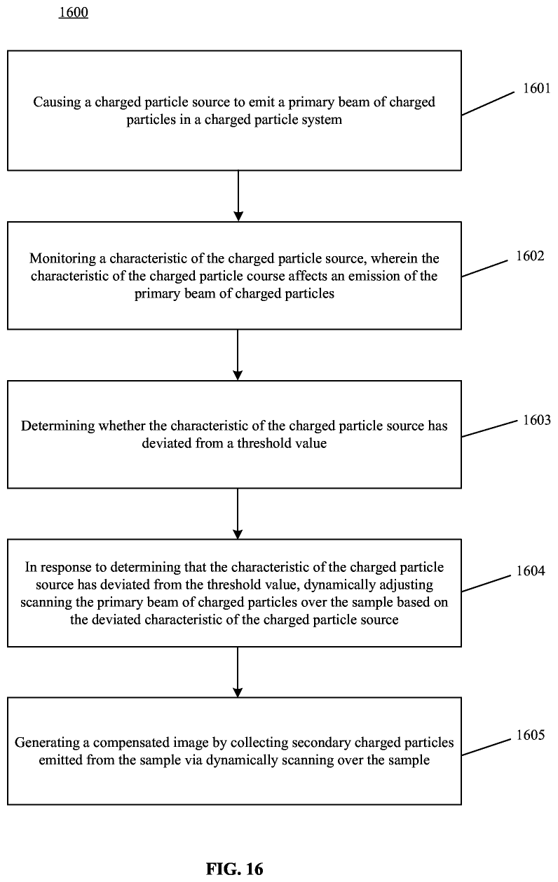

Reference is now made to FIG. 16, which is a flowchart representing an example process for compensating electron beam variations in generating a SEM image, consistent with embodiments of the present disclosure. The steps of method 1600 may be performed by an apparatus with a single-beam (e.g., FIG. 2) or a multi-beam column structure, for example, shown in FIG. 3, executing on or otherwise using the features of a computing device (e.g., controller 109 of FIG. 1). It is appreciated that the illustrated method 1600 may be altered to modify the order of steps and to include additional steps. The steps of method 1600 may be applicable to any of the embodiments as described above and illustrated in the preceding figures.

In step 1601, a primary electron beam is emitted from the electron source. The primary electron beam may be comprised of any number of electrons.

In step 1602, a characteristic of the primary electron beam is monitored. The characteristic of the primary beam may be an emission current value. In some embodiments, the characteristic of the primary beam is monitored at the electron source using a monitoring component (e.g., monitoring component 401 of FIG. 4). In some embodiments, the characteristic of the primary beam is monitored at a location downstream of an electron source. In some embodiments, the characteristic of the primary beam may be monitored by an auxiliary detector (e.g., auxiliary detector 652 of FIG. 6A, auxiliary detector 752 of FIG. 7, or auxiliary detector 1052 of FIGS. 10A-10D).

In step 1603, a deviation from a threshold value for the characteristic of the primary beam is determined. A threshold value may be determined based on a percentage of a target characteristic of the primary beam. As a non-limiting example, a target characteristic of the primary beam may be an emission current of 1 nA. The threshold value may be determined to be a 10% difference from the target emission current of 1 nA.

In step 1604, a scan of the primary beam of charged particles is dynamically adjusted over the sample in response to determining whether the measured characteristic of the charged particle source has deviated outside the threshold value. In some embodiments, a constant dose of charged particles impacting the sample as the charged particle beam is scanned over the sample. An electrical signal is applied to a deflector to scan the charged particle beam at different speeds at different times across the sample. In some embodiments, if a charged particle source deviation causes a change in an emission current, a dynamically adjusted scan of the charged particle beam normalizes the charged particle dose at different areas on the sample. In some embodiments, an electrical signal of a first magnitude is applied based on whether the scanning is over the first type of area associated with the first pixel size and an electrical signal of a second magnitude is applied based on whether the scanning is over the second type of area associated with the second pixel size. In some embodiments, the electrical signal is applied to a charged-particle beam apparatus. In some embodiments, the charged-particle beam apparatus is a single-beam tool (e.g., FIG. 2) or a multi-beam tool (e.g., FIG. 3). In some embodiments, the electrical signal is applied to a deflector (e.g., deflectors 233 of FIG. 2 or deflection scanning unit 326 of FIG. 3) of the charged-particle beam apparatus. In some embodiments, an electrical signal associated with a larger applied rate to the deflector causes the charged-particle beam to scan more quickly across an area of the sample.

In step 1605, a compensated image is generated by collecting secondary charged particles emitted from the sample via the dynamic scanning over the sample. The secondary charged particles may be collected on an “event-basis” as described above (e.g., FIGS. 12A and 12B). Step 1605 may be performed by an image processor. The image processor (e.g., image processing system 290 of FIG. 2, image processing system 390 of FIG. 3, or image processing system 1209 of FIGS. 12A and 12B) may normalize detection data during imaging and compensate for deviations from the charged particle source. In some embodiments, the compensated image may have improved image quality. In some embodiments, the compensated image may have improved signal-to-noise ratio. In some embodiments, the compensated image may have improved brightness, improved contrast, improved focus, or other improved image characteristics. The compensated image may be used to improve defect inspection or metrology measurements of the sample.

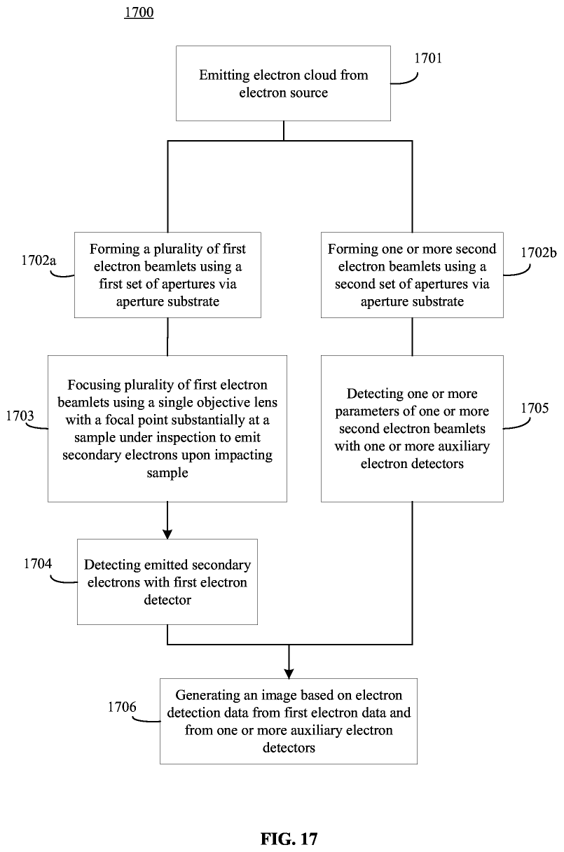

Reference is now made to FIG. 17, which is a flowchart representing an example process for compensating electron beam variations in generating an SEM image, consistent with embodiments of the present disclosure. The steps of method 1700 may be performed by an apparatus with the multi-beam column structure, for example, shown in FIG. 3, executing on or otherwise using the features of a computing device (e.g., controller 109 of FIG. 1). It is appreciated that the illustrated method 1700 may be altered to modify the order of steps and to include additional steps. The steps of method 1700 may be applicable to embodiments as described above and illustrated in preceding figures.

In step 1701, a primary electron beam is emitted from the electron source. The primary electron beam may be comprised of any number of electrons.

In step 1702a, a plurality of first electron beamlets may form upon the electrons in the emitted primary electron beam passing through a first set of apertures on an aperture substrate. In step 1702b, one or more second electron beamlets may form upon the electrons in the emitted primary electron beam passing through a second set of apertures on the aperture substrate. The first and second set of apertures may be the same diameter. The second set of apertures may be smaller in diameter than the first set of apertures. The second set of apertures may comprise one second aperture. The second set of apertures may be positioned outside or interspersed between the array of the first set of apertures. It is appreciated that steps 1702a and 1702b may occur simultaneously or independently. It is appreciated that the plurality of first electron beamlets formed in step 1702a and the one or more second electron beamlets formed in step 1702b are separate and active at the same time.

In step 1703, using a single objective lens, the plurality of first electron beamlets are focused to a focal point substantially at a sample surface under inspection. It is appreciated that each of the plurality of first electron beamlets may be focused using the same objective lens. Upon impacting the sample, secondary electrons may be emitted from the sample.

In step 1704, the emitted secondary electrons are detected by a first electron detector. The first electron detector may be an electron detection device and may be communicatively coupled to an image processing system through a medium such as an electric conductor, optical fiber cable, portable storage media, IR, Bluetooth, internet, wireless network, or wireless radio. The electron detection data from the captured secondary electrons emitted from the plurality of first electron beamlets impacting the sample may be delivered to the image processing system.

In step 1705, the one or more second electron beamlets may impact one or more auxiliary electron detectors to detect one or more parameters of the one or more second electron beamlets. It is appreciated that the one or more second electron beamlets may at least partially impact the one or more auxiliary electron detectors. It is appreciated that the one or more auxiliary electron detectors may comprise a plurality of detection segments or may be pixelated. It is appreciated that the one or more second electron beamlets may not be focused by the objective lens and do not reach the sample. In some embodiments, the one or more auxiliary electron detectors may be positioned on the aperture substrate. In some embodiments, the one or more auxiliary electron detectors may be positioned below (i.e., down-beam) the aperture substrate and above (i.e., up-beam) the objective lens on the same vertical axis as the second beamlet aperture. In some embodiments, the one or more auxiliary electron detectors may continuously monitor the one or more second electron beamlets. The one or more auxiliary electron detectors may be communicatively coupled to an image processing system through a medium such as an electric conductor, optical fiber cable, portable storage media, IR, Bluetooth, internet, wireless network, or wireless radio. The one or more auxiliary electron detectors may include circuitry configured to measure parameter fluctuations of the one or more second electron beamlets that may be attributed to the electron source including, but not limited to, fluctuations of electron source tip current, angular distribution of electron source tip emitted-current density, electron source tip position, tip region emitting electrons, long-term electron source tip drift, beamlet emission fluctuation, and other aberrations of the electron source occurring during operation. One or more parameter fluctuations measured by the one or more auxiliary electron detectors (e.g., the detection data from the one or more second electron detectors) may be delivered to an image processing system.

In step 1706, an image is generated based on the electron detection data from the plurality of first electron beamlets and based on the electron detection data from the one or more auxiliary electron detectors. The electron detection data from the one or more auxiliary electron detectors may compensate for electron source fluctuations in electron detection data from the plurality of first electron beamlets. The generated image may have improved quality compared to an image generated based on the electron detection data from the plurality of first electron beamlets alone. The generated image may have improved signal-to-noise ratio. The generated image may have improved contrast. The generated image may have improved metrology measurement accuracy. Step 1706 may be performed by an image processing system.

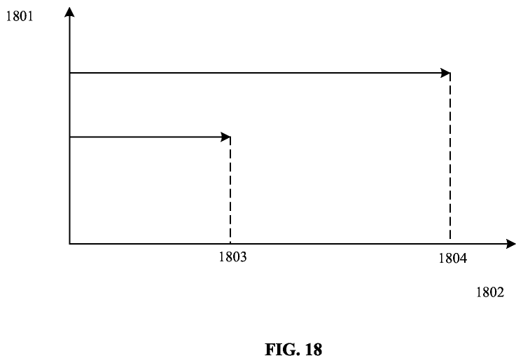

Reference is now made to FIG. 18, which is an example illustration of a longer duration of a charged particle apparatus for inspection or metrology, consistent with embodiments of the present disclosure. FIG. 18 illustrates a charged particle source 1801 operating for a period of time 1802. According to conventional methods and systems, a charged particle apparatus may be operational for a time period 1803. After time 1803, instrument shutdown is necessary because the charged particle source characteristic has fluctuated past a threshold value and cannot be sustained. This may decrease throughput for, e.g., inspection and metrology. According to embodiments of the present disclosure, a charged particle apparatus may be operational for a time period 1804. It is appreciated that time period 1803 and 1804 are illustrated at different heights on the y-axis for comparative purposes. FIG. 18 illustrates time period 1804 is longer than time period 1803. Thus, embodiments of the present disclosure increase operation time for inspection and metrology before a shutdown may be needed. Thus, throughput is increased.

A non-transitory computer readable medium may be provided that may store instructions for a processor of a controller (e.g., controller 109 of FIG. 1) to perform inspection image acquisition, stage positioning, beam focusing, electric field adjustments, objective lens adjusting, activating electron source, method 1400, to determine electrical signals associated with dynamic scanning adjustment, method 1600, method 1700, and other executable functions in the charged particle system relating to the electron beam current variation compensation and inspection method. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:

1. A method of compensating for variations in charged particle beam current in generation of an image of a sample, comprising:
causing a charged particle source to emit a primary beam of charged particles;
forming a first set of charged particle beamlets using a first set of apertures on an aperture substrate by passing a portion of charged particles of the primary beam of charged particles through the first set of apertures, wherein secondary charged particles emitted in response to the first set of charged particle beamlets impacting the sample are detected by one or more first detectors;
focusing the first set of charged particle beamlets using an objective lens to a focal point substantially at the sample;
forming a second charged particle beamlet using a second aperture on the aperture substrate by passing a portion of charged particles of the primary beam of charged particles through the second aperture, wherein the second charged particle beamlet is active at a same time as the first set of charged particle beamlets and is directed to an auxiliary detector without interacting with the sample, and the first set of charged particle beamlets and the second charged particle beamlet have no beamlet in common; and
generating an image based on detection data from the one or more first detectors and based on detection data from the auxiliary detector.

2. The method of clause 1, wherein the second charged particle beamlet is not focused by the objective lens.

3. The method of clause 1, wherein the aperture substrate is a top layer of a layered structure comprising a plurality of layered optical elements.

4. The method of any one of clauses 1-3, wherein the second aperture is positioned at a minimum distance from the first set of apertures on the aperture substrate.

5. The method of any one of clauses 1-3, wherein the second aperture is positioned between the first set of apertures on the aperture substrate.

6. The method of clauses 5, wherein the second aperture is positioned closer to an optical axis than at least one of the apertures in the first set of apertures.

7. The method of clause 1, further comprising obtaining information about a parameter of the second charged particle beamlet using the auxiliary detector.

8. The method of clause 7, wherein the auxiliary detector is configured to continuously monitor the parameter of the second charged particle beamlet.

9. The method of clause 7, wherein the auxiliary detector comprises a plurality of segments to monitor the parameter of the second charged particle beamlet.

10. The method of clause 7, wherein the parameter of the second charged particle beamlet is related to a corresponding parameter of the first set of charged particle beamlets.

11. The method of clause 10, wherein the parameter of the second charged particle beamlet is off-axis aberration.

12. The method of clause 11, wherein the obtained information about the parameter of the second charged particle beamlet is attributed to the charged particle source.

13. The method of clause 7, wherein the parameter of the second charged particle beamlet is at least one of:
a fluctuation of a source tip current,
an angular distribution of a tip emitted-current density,
a virtual source tip position,
a long-term source tip drift, or
an emission fluctuation.

14. The method of clause 1, wherein the detection data from the auxiliary detector is used to normalize the detection data from the one or more first detectors.

15. The method of clause 14, wherein the detection data from the auxiliary detector is used to improve a signal-to-noise ratio of the image generated.

16. The method of clause 14, wherein the detection data from the auxiliary detector is used to improve a contrast of the image generated.

17. The method of clause 14, wherein the detection data from the auxiliary detector is used to improve metrology measurement accuracy.

18. The method of any one of clauses 1-3 and 7-17, wherein the aperture substrate has an up-beam surface and a down-beam surface.

19. The method of clause 18, wherein the auxiliary detector is located between the up-beam surface of the aperture substrate and the objective lens.

20. The method of clause 18, wherein the auxiliary detector is placed on the aperture substrate and level or flush with an opening of the second aperture.

21. The method of clause 18, wherein the auxiliary detector is located between the layers of the optical elements comprising the layered structure.

22. The method of clause 18, wherein the auxiliary detector is located on the layers of the optical elements comprising the layered structure.

23. The method of any one of clauses 18-22, wherein the auxiliary detector is placed on a same vertical axis of the second aperture.

24. The method of clause 1, wherein the second aperture is a part of a second set of apertures associated with one or more auxiliary detectors.

25. The method of clause 24, wherein the second set of apertures further comprises a third aperture configured to form a third charged particle beamlet.

26. The method of clause 25, wherein the second charged particle beamlet and the third charged particle beamlet are monitored for a parameter of the second and third charged particle beamlets in an X-axis.

27. The method of clause 25, wherein the second charged particle beamlet and the third charged particle beamlet are monitored for a parameter of the second and third charged particle beamlets in a Y-axis.

28. The method of clauses 26 or 27, wherein the parameter of the second and third charged particle beamlets is attributed to a parameter of the set of first charged particle beamlets.

29. The method of clauses 26 or 27, wherein the parameter of the second and third charged particle beamlets is attributed to a parameter of the charged particle source.

30. An apparatus for inspecting a sample, comprising:
a charged particle source configured to emit a primary beam of charged particles;
an aperture substrate comprising:
a first set of apertures configured to form a first set of charged particle beamlets by passing through a portion of charged particles of the primary beam of charged particles; and
a second aperture configured to form a second charged particle beamlet by passing through another portion of charged particles of the primary beam of charged particles, wherein the second charged particle beamlet is active at a same time as the first set of charged particle beamlets, and the first set of charged particle beamlets and second charged particle beamlet have no beamlet in common;
one or more first detectors to detect secondary charged particles emitted in response to the first set of charged particle beamlets impacting the sample;
an auxiliary detector configured to monitor the second charged particle beamlet, wherein the second charged particle beamlet is directed to the auxiliary detector without interacting with the sample; and an image processor configured to generate an image based on detection data from the one or more first detectors and based on detection data from the auxiliary electron detector.

31. The apparatus of clause 30, further comprising an objective lens configured to focus the first set of charged particle beamlets to a focal point substantially at the sample, wherein the second charged particle beamlet is not focused by the objective lens.

32. The apparatus of clause 30, wherein the aperture substrate is a top layer of a layered structure comprising a plurality of layered optical elements.

33. The apparatus of any one of clauses 30-32, wherein the second aperture is positioned at a minimum distance from the first set of apertures on the aperture substrate.

34. The apparatus of any one of clauses 30-32, wherein the second aperture is positioned between the first set of apertures on the aperture substrate.

35. The apparatus of clause 34, wherein the second aperture is positioned closer to an optical axis than at least one of the apertures in the first set of apertures.

36. The apparatus of clause 30, wherein the auxiliary detector is configured to obtain information about a parameter of the second charged particle beamlet.

37. The apparatus of clause 36, wherein the auxiliary detector is configured to continuously monitor the parameter of the second charged particle beamlet.

38. The apparatus of clause 36, wherein the auxiliary detector comprises a plurality of segments to monitor the parameter of the second charged particle beamlet.

39. The apparatus of clause 36, wherein the parameter of the second charged particle beamlet is related to a corresponding parameter of the first set of charged particle beamlets.

40. The apparatus of clause 39, wherein the parameter of the second charged particle beamlet is off-axis aberration.

41. The apparatus of clause 40, wherein the obtained information about the parameter of the second charged particle beamlet is attributed to the charged particle source.

42. The apparatus of clause 36, wherein the parameter of the second charged particle beamlet is at least one of:
a fluctuation of a source tip current,
an angular distribution of a tip emitted-current density,
a virtual source tip position,
a long-term source tip drift, or
an emission fluctuation.

43. The apparatus of clause 30, wherein the detection data from the auxiliary detector is used to normalize the detection data from the one or more first detectors.

44. The apparatus of clause 43, wherein the detection data from the auxiliary detector is used to improve a signal-to-noise ratio of the image generated.

45. The apparatus of clause 43, wherein the detection data from the auxiliary detector is used to improve a contrast of the image generated.

46. The apparatus of clause 43, wherein the detection data from the auxiliary detector is used to improve metrology measurement accuracy.

47. The apparatus of any one of clauses 30-32 and 36-46, wherein the aperture substrate has an up-beam surface and a down-beam surface.

48. The apparatus of clause 47, wherein the auxiliary detector is located between the up-beam surface of the aperture substrate and the objective lens.

49. The apparatus of clause 47, wherein the auxiliary detector is placed on the aperture substrate and level or flush with an opening of the second aperture.

50. The apparatus of clause 47, wherein the auxiliary detector is located between the layers of the optical elements comprising the layered structure.

51. The apparatus of clause 47, wherein the auxiliary detector is located on the layers of the optical elements comprising the layered structure.

52. The apparatus of any one of clauses 48-51, wherein the auxiliary detector is placed on a same vertical axis of the second aperture.

53. The apparatus of clause 30, wherein the second aperture is a part of a second set of apertures associated with one or more auxiliary detectors.

54. The apparatus of clause 53, wherein the second set of apertures further comprises a third aperture configured to form a third charged particle beamlet.

55. The apparatus of clause 54, wherein the second charged particle beamlet and the third charged particle beamlet are monitored for a parameter of the second and third charged particle beamlets in an X-axis.

56. The apparatus of clause 54, wherein the second charged particle beamlet and the third charged particle beamlet are monitored for a parameter of the second and third charged particle beamlets in a Y-axis.

57. The apparatus of clauses 55 or 56, wherein the parameter of the second and third charged particle beamlets is attributed to a parameter of the first set of charged particle beamlets.

58. The apparatus of clauses 55 or 56, wherein the parameter of the second and third charged particle beamlets is attributed to a parameter of the charged particle source.

59. A non-transitory computer readable medium storing a set of instructions that is executable by one or more processors of a charged particle beam apparatus to cause the charged particle beam apparatus to perform a method of inspecting a sample, the method comprising:
causing a charged particle source to emit a primary beam of charged particles;
forming a first set of charged particle beamlets using a first set of apertures on an aperture substrate by passing a portion of charged particles of the primary beam of charged particles through the first set of apertures, wherein secondary charged particles emitted in response to the first set of charged particle beamlets impacting the sample are detected by one or more first detectors;
focusing the first set of charged particle beamlets using an objective lens to a focal point substantially at the sample;
forming a second charged particle beamlet using a second aperture on the aperture substrate by passing a portion of charged particles of the primary beam of charged particles through the second aperture, wherein the second charged particle beamlet is active at a same time as the first set of charged particle beamlets and is directed to an auxiliary detector without interacting with the sample, and the first set of charged particle beamlets and the second charged particle beamlet have no beamlet in common; and
generating an image based on detection data from the one or more first detectors and based on detection data from the auxiliary detector.

60. The non-transitory computer readable medium of clause 59, wherein the second charged particle beamlet is not focused by the objective lens.

61. The non-transitory computer readable medium of clause 59, wherein the aperture substrate is a top layer of a layered structure comprising a plurality of layered optical elements.

62. The non-transitory computer readable medium of any one of clauses 59-61, wherein the second aperture is positioned at a minimum distance from the first set of apertures on the aperture substrate.

63. The non-transitory computer readable medium of any one of clauses 59-61, wherein the second aperture is positioned between the first set of apertures on the aperture substrate.

64. The non-transitory computer readable medium of clause 63, wherein the second aperture is positioned closer to an optical axis than at least one of the apertures in the first set of apertures.

65. The non-transitory computer readable medium of clause 59, wherein the set of instructions that is executable by the one or more processors to cause the charged particle beam apparatus to further perform:
obtaining information about a parameter of the second charged particle beamlet using the auxiliary detector.

66. The non-transitory computer readable medium of clause 65, wherein the auxiliary detector is configured to continuously monitor the parameter of the second charged particle beamlet.

67. The non-transitory computer readable medium of clause 65, wherein the auxiliary detector comprises a plurality of segments to monitor the parameter of the second charged particle beamlet.

68. The non-transitory computer readable medium of clause 65, wherein the parameter of the second charged particle beamlet is related to a corresponding parameter of the first set of charged particle beamlets.

69. The non-transitory computer readable medium of clause 68, wherein the parameter of the second charged particle beamlet is off-axis aberration.

70. The non-transitory computer readable medium of clause 69, wherein the obtained information about the parameter of the second charged particle beamlet is attributed to the charged particle source.

71. The non-transitory computer readable medium of clause 65, wherein the parameter of the second charged particle beamlet is at least one of:
a fluctuation of a source tip current,
an angular distribution of a tip emitted-current density,
a virtual source tip position,
a long-term source tip drift, or
an emission fluctuation.

72. The non-transitory computer readable medium of clause 59, wherein the detection data from the auxiliary detector is used to normalize the detection data from the one or more first detectors.

73. The non-transitory computer readable medium of clause 72, wherein the detection data from the auxiliary detector is used to improve a signal-to-noise ratio of the image generated.

74. The non-transitory computer readable medium of clause 72, wherein the detection data from the auxiliary detector is used to improve a contrast of the image generated.

75. The non-transitory computer readable medium of clause 72, wherein the detection data from the auxiliary detector is used to improve metrology measurement accuracy.

76. The non-transitory computer readable medium of any one of clauses 59-61 and 65-75, wherein the aperture substrate has an up-beam surface and a down-beam surface.

77. The non-transitory computer readable medium of clause 76, wherein the auxiliary detector is located between the up-beam surface of the aperture substrate and the objective lens.

78. The non-transitory computer readable medium of clause 76, wherein the auxiliary detector is placed on the aperture substrate and level or flush with an opening of the second aperture.

79. The non-transitory computer readable medium of clause 76, wherein the auxiliary detector is located between the layers of the optical elements comprising the layered structure.

80. The non-transitory computer readable medium of clause 76, wherein the auxiliary detector is located on the layers of the optical elements comprising the layered structure.

81. The non-transitory computer readable medium of any one of clauses 76-80, wherein the auxiliary detector is placed on a same vertical axis of the second aperture.

82. The non-transitory computer readable medium of clause 59, wherein the second aperture is a part of a second set of apertures associated with one or more auxiliary detectors.

83. The non-transitory computer readable medium of clause 82, wherein the second set of apertures further comprises a third aperture configured to form a third charged particle beamlet.

84. The non-transitory computer readable medium of clause 83, wherein the second charged particle beamlet and the third charged particle beamlet are monitored for a parameter of the second and third charged particle beamlets in an X-axis.

85. The non-transitory computer readable medium of clause 83, wherein the second charged particle beamlet and the third charged particle beamlet are monitored for a parameter of the second and third charged particle beamlets in a Y-axis.

86. The non-transitory computer readable medium of clauses 84 or 85, wherein the parameter of the second and third charged particle beamlets is attributed to a parameter of the set of first charged particle beamlets.

87. The non-transitory computer readable medium of clauses 84 or 85, wherein the parameter of the second and third charged particle beamlets is attributed to a parameter of the charged particle source.

88. A method for compensating for variations in charged particle beam current in generation of an image of a sample, comprising:
causing a charged particle source to emit a primary beam of charged particles in a charged particle system;
monitoring a characteristic of the charged particle source, wherein the characteristic of the charged particle source affects an emission of the primary beam of charged particles;
determining whether the characteristic of the charged particle source has deviated from a threshold value;
measuring a characteristic for a secondary charged particle emitted from the sample via scanning the primary beam of charged particles over the sample using an image detector;
in response to the determination that the characteristic of the charged particle source has deviated from the threshold value, determining a characteristic of the charged particle source based on the measured characteristic of the secondary charged particle to compensate for the deviated characteristic of the charged particle source; and
applying the determined characteristic of the charged particle source to the image detector to generate a compensated image of the sample.

89. The method of clause 88, wherein monitoring the characteristic of the charged particle source comprises directly measuring the charged particle source.

90. The method of clause 89, wherein the characteristic of the charged particle source is an emission current value.

91. The method of clause 88, wherein monitoring the characteristic of the charged particle source comprises indirectly measuring the charged particle source.

92. The method of clause 91, wherein the characteristic of the charged particle source is measured by monitoring the primary beam of charged particles.

93. The method of clause 92, wherein an auxiliary detector positioned at a downstream location of the charged particle source monitors a parameter of the primary beam of charged particles.

94. The method of clause 93, wherein the auxiliary detector is configured to continuously monitor the parameter of the primary beam of charged particles.

95. The method of any one of clauses 92 to 94, wherein information obtained by monitoring the primary beam of charged particles is attributed to the charged particle source.

96. The method of any one of clauses 92 to 95, wherein information obtained by monitoring the primary beam of charged particles is at least one of:
a fluctuation of a source tip current,
an angular distribution of a tip emitted-current density,
a virtual source tip position,
a long-term source tip drift, or
an emission fluctuation.

97. The method of any one of clauses 88 to 96, wherein information obtained by monitoring the characteristic of the charged particle source is used to normalize detection data from the image detector.

98. The method of any one of clauses 88 to 97, wherein measuring the characteristic of the secondary charged particle comprises measuring a landing event of the secondary charged particle.

99. The method of clause 98, wherein the image detector measures a number of secondary charged particles impacting the image detector during the landing event.

100. The method of clause 98 or 99, wherein measuring the characteristic of the secondary charged particle comprises measuring a timestamp of the landing event.

101. The method of clause 100, further comprising determining a current on a surface of the sample based on the landing event and the timestamp.

102. The method of any one of clauses 88 to 101, wherein applying the determined characteristic of the charged particle source to the image detector normalizes detection data of the image detector.

103. The method of any one of clauses 88 to 101, wherein applying the determined characteristic of the charged particle source to the image detector improves a signal-to-noise ratio of the compensated image.

104. The method of any one of clauses 88 to 101, wherein applying the determined characteristic of the charged particle source to the image detector improves a brightness of the compensated image.

105. The method of any one of clauses 88 to 101, wherein applying the determined characteristic of the charged particle source to the image detector improves a contrast of the compensated image.

106. The method of any one of clauses 88 to 101, wherein applying the determined characteristic of the charged particle source to the image detector improves metrology measurement and inspection measurement accuracy of the compensated image.

107. The method of any one of clauses 88 to 106, wherein the charged particle system is a scanning electron microscope.

108. A method for compensating for variations in charged particle beam current in generation of an image of a sample, comprising:
causing a charged particle source to emit a primary beam of charged particles in a charged particle system;
monitoring a characteristic of the charged particle source, wherein the characteristic of the charged particle source affects an emission of the primary beam of charged particles;
determining whether the characteristic of the charged particle source has deviated from a threshold value;
in response to the determination that the characteristic of the charged particle source has deviated from the threshold value, dynamically adjusting scanning the primary beam of charged particles over the sample based on the deviated characteristic of the charged particle source; and
generating a compensated image by collecting secondary charged particles emitted from the sample via scanning the primary beam of charged particles over the sample via an image detector.

109. The method of clause 108, wherein monitoring the characteristic of the charged particle source comprises directly measuring the charged particle source.

110. The method of clause 109, wherein the characteristic of the charged particle source is an emission current value.

111. The method of clause 108, wherein monitoring the characteristic of the charged particle source comprises indirectly measuring the charged particle source.

112. The method of clause 111, wherein the characteristic of the charged particle source is measured by monitoring the primary beam of charged particles.

113. The method of clause 112, wherein an auxiliary detector positioned at a downstream location of the charged particle source monitors a parameter of the primary beam of charged particles.

114. The method of clause 113, wherein the auxiliary detector is configured to continuously monitor the parameter of the primary beam of charged particles.

115. The method of any one of clauses 112 to 114, wherein information obtained by monitoring the primary beam of charged particles is attributed to the charged particle source.

116. The method of any one of clauses 112 to 115, wherein information obtained by monitoring the primary beam of charged particles is at least one of:
a fluctuation of a source tip current,
an angular distribution of a tip emitted-current density,
a virtual source tip position,
a long-term source tip drift, or
an emission fluctuation.

117. The method of any one of clauses 108 to 116, wherein information obtained by monitoring the characteristic of the charged particle source is used to normalize detection data from the image detector.

118. The method of any one of clauses 108 to 117, wherein dynamically adjusting scanning the primary beam of charged particles over the sample comprises:
applying an electrical signal at a rate of a first magnitude when the characteristic of the charged particle source has deviated above a target threshold value; and
applying an electrical signal at a rate of a second magnitude when the characteristic of the charged particle source has deviated below a target threshold value.

119. The method of clause 118, wherein dynamically adjusting scanning the primary beam of charged particles increases a scan speed across the sample.

120. The method of clause 118, wherein dynamically adjusting scanning the primary beam of charged particles decreases a scan speed across the sample.

121. The method of any one of clauses 118 to 120, wherein the electrical signal is a voltage.

122. The method of any one of clauses 118 to 120, wherein the electrical signal is a current.

123. The method of any one of clauses 108 to 122, wherein dynamically adjusting scanning the primary beam of charged particles is maintained at a constant dose of charged particles per area on the sample.

124. The method of clause 123, wherein the area on the sample is a pixel.

125. The method of any one of clauses 108 to 124, wherein the compensated image has an improved signal-to-noise ratio.

126. The method of any one of clauses 108 to 124, wherein the compensated image has an improved brightness.

127. The method of any one of clauses 108 to 124, wherein the compensated image has an improved contrast.

128. The method of any one of clauses 108 to 127, wherein the compensated image is used for defect inspection of the sample.

129. The method of any one of clauses 108 to 127, wherein the compensated image is used to collect a metrology measurement.

130. The method of any one of clauses 108 to 129, wherein the charged particle system is a scanning electron microscope.

131. An apparatus for compensating for variations in charged particle beam current in generation of an image of a sample, comprising:
a charged particle source configured to emit a primary beam of charged particles;
a monitoring component including circuitry configured to monitor a characteristic of the charged particle source and to determine whether the characteristic of the charged particle source has deviated from a threshold value, wherein the characteristic of the charged particle source affects an emission of the primary beam of charged particles;
an image detector configured to measure a characteristic for a secondary charged particle emitted from the sample via scanning the primary beam of charged particles over the sample; and
an image processor including circuitry configured to determine a characteristic of the charged particle source based on the measured characteristic of the secondary charged particle to compensate for the deviated characteristic of the charged particle source, if the characteristic of the charged particle source has deviated from the threshold value and to generate a compensated image of the sample based on the determined characteristic of the charged particle source.

132. The apparatus of clause 131, wherein the monitoring component includes circuitry configured to monitor the characteristic of the charged particle source by a direct measurement of the charged particle source.

133. The apparatus of clause 132, wherein the characteristic of the charged particle source is an emission current value.

134. The apparatus of clause 131, wherein the monitoring component includes circuitry configured to monitor the characteristic of the charged particle source by an indirect measurement of the charged particle source.

135. The apparatus of clause 134, wherein the characteristic of the charged particle source is measured by monitoring the primary beam of charged particles.

136. The apparatus of clause 135, wherein the monitoring component is positioned at a downstream location of the charged particle source.

137. The apparatus of clause 136, wherein the monitoring component includes circuitry configured to continuously monitor a parameter of the primary beam of charged particles.

138. The apparatus of any one of clauses 135 to 137, wherein information obtained by the monitoring component is attributed to the charged particle source.

139. The apparatus of any one of clauses 135 to 138, wherein information obtained by the monitoring component is at least one of:
a fluctuation of a source tip current,
an angular distribution of a tip emitted-current density,
a virtual source tip position,
a long-term source tip drift, or
an emission fluctuation.

140. The apparatus of any one of clauses 131 to 139, wherein information obtained by the monitoring component is used to normalize detection data from the image detector.

141. The apparatus of any one of clauses 131 to 140, wherein the image detector is configured to measure a landing event of the secondary charged particle.

142. The apparatus of clause 141, wherein the image detector is configured to measure a number of secondary charged particles impacting the image detector during the landing event.

143. The apparatus of clause 141 or 142, wherein measuring the characteristic of the secondary charged particle comprises measuring a timestamp of the landing event.

144. The apparatus of clause 143, wherein the image detector is further configured to determine a current on a surface of the sample based on the landing event and the timestamp.

145. The apparatus of any one of clauses 131 to 144, wherein applying the determined characteristic of the charged particle source to the image detector normalizes detection data of the image detector.

146. The apparatus of any one of clauses 131 to 145, wherein the image processor includes circuitry configured to generate a compensated image with an improved signal-to-noise ratio.

147. The apparatus of any one of clauses 131 to 145, wherein the image processor includes circuitry configured to generate a compensated image with an improved brightness.

148. The apparatus of any one of clauses 131 to 145, wherein the image processor includes circuitry configured to generate a compensated image with an improved contrast.

149. The apparatus of any one of clauses 131 to 148, wherein the compensated image is used for defect inspection of the sample.

150. The apparatus of any one of clauses 131 to 148, wherein the compensated image is used to collect a metrology measurement.

151. The apparatus of any one of clauses 131 to 150, wherein the apparatus is a charged particle apparatus.

152. The apparatus of clause 151, wherein the apparatus is a scanning electron microscope.

153. An apparatus for compensating for variations in charged particle beam current in generation of an image of a sample, comprising:
a charged particle source configured to emit a primary beam of charged particles;
a monitoring component includes circuitry configured to monitor a characteristic of the charged particle source and determine whether the characteristic of the charged particle source has deviated from a threshold value, wherein the characteristic of the charged particle source affects an emission of the primary beam of charged particles;
a deflector configured to dynamically adjust scanning the primary beam of charged particles over the sample based on the deviated characteristic of the charged particle source;
an image detector configured to collect secondary charged particles emitted from the sample via scanning the primary beam of charged particles over the sample; and
an image processor includes circuitry configured to generate a compensated image from the collected secondary charged particles.

154. The apparatus of clause 153, wherein the monitoring component includes circuitry configured to monitor the characteristic of the charged particle source by a direct measurement of the charged particle source.

155. The apparatus of clause 154, wherein the characteristic of the charged particle source is an emission current value.

156. The apparatus of clause 153, wherein the monitoring component is configured to includes circuitry configured to monitor the characteristic of the charged particle source by an indirect measurement of the charged particle source.

157. The apparatus of clause 156, wherein the characteristic of the charged particle source is measured by monitoring the primary beam of charged particles.

158. The apparatus of clause 157, wherein the monitoring component is positioned at a downstream location of the charged particle source.

159. The apparatus of clause 158, wherein the monitoring component includes circuitry configured to continuously monitor a parameter of the primary beam of charged particles.

160. The apparatus of any one of clauses 157 to 159, wherein information obtained by the monitoring component is attributed to the charged particle source.

161. The apparatus of any one of clauses 157 to 160, wherein information obtained by the monitoring component is at least one of:
a fluctuation of a source tip current,
an angular distribution of a tip emitted-current density,
a virtual source tip position,
a long-term source tip drift, or
an emission fluctuation.

162. The apparatus of any one of clauses 153 to 161, wherein information obtained by the monitoring component is used to normalize detection data from the image detector.

163. The apparatus of any one of clauses 153 to 162, wherein the deflector is configured to: apply an electrical signal at a rate of a first magnitude when the deviated characteristic value of the charged particle source is above a target threshold value; and
apply an electrical signal at a rate of a second magnitude when the deviated characteristic value of the charged particle source is below a threshold value.

164. The apparatus of clause 163, wherein dynamically adjusting scanning the primary beam of charged particles increases a scan speed across the sample.

165. The apparatus of clause 163, wherein dynamically adjusting scanning the primary beam of charged particles decreases a scan speed across the sample.

166. The apparatus of any one of clauses 163 to 165, wherein the electrical signal is a voltage.

167. The apparatus of any one of clauses 163 to 165, wherein the electrical signal is a current.

168. The apparatus of any one of clauses 153 to 167, wherein the deflector is configured to dynamically adjust scanning the primary beam of charged particles at a constant dose of charged particles per area on the sample.

169. The apparatus of clause 168, wherein the area on the sample is a pixel.

170. The apparatus of any one of clauses 153 to 169, wherein the compensated image has an improved signal-to-noise ratio.

171. The apparatus of any one of clauses 153 to 169, wherein the compensated image has an improved brightness.

172. The apparatus of any one of clauses 153 to 169, wherein the compensated image has an improved contrast.

173. The apparatus of any one of clauses 153 to 172, wherein the compensated image is used for defect inspection of the sample.

174. The apparatus of any one of clauses 153 to 172, wherein the compensated image is used to collect a metrology measurement.

175. The apparatus of any one of clauses 153 to 174, wherein the apparatus is a charged particle apparatus.

176. The apparatus of clause 175, wherein the apparatus is a scanning electron microscope.

177. A non-transitory computer readable medium comprising a set of instructions that is executable by one or more processors of a computing device to cause the computing device to perform operations for compensating for variations in charged particle beam current in generation of an image of a sample, the operations comprising:
causing a charged particle source to emit a primary beam of charged particles in a charged particle system;
monitoring a characteristic of the charged particle source, wherein the characteristic of the charged particle source affects an emission of the primary beam of charged particles;
determining whether the characteristic of the charged particle source has deviated from a threshold value;
measuring a characteristic for a secondary charged particle emitted from the sample via scanning the primary beam of charged particles over the sample using an image detector;
in response to the determination that the characteristic of the charged particle source has deviated from the threshold value, determining a characteristic of the charged particle source based on the measured characteristic of the secondary charged particle to compensate for the deviated characteristic of the charged particle source; and
applying the determined characteristic of the charged particle source to the image detector to generate a compensated image of the sample.

178. The non-transitory computer readable medium of clause 177, wherein monitoring the characteristic of the charged particle source comprises directly measuring the charged particle source.

179. The non-transitory computer readable medium of clause 178, wherein the characteristic of the charged particle source is an emission current value.

180. The non-transitory computer readable medium of clause 177, wherein monitoring the characteristic of the charged particle source comprises indirectly measuring the charged particle source.

181. The non-transitory computer readable medium of clause 180, wherein the characteristic of the charged particle source is measured by monitoring the primary beam of charged particles.

182. The non-transitory computer readable medium of clause 181, wherein an auxiliary detector positioned at a downstream location of the charged particle source monitors a parameter of the primary beam of charged particles.

183. The non-transitory computer readable medium of clause 182, wherein the auxiliary detector includes circuitry configured to continuously monitor the parameter of the primary beam of charged particles.

184. The non-transitory computer readable medium of any one of clauses 181 to 183, wherein information obtained by monitoring the primary beam of charged particles is attributed to the charged particle source.

185. The non-transitory computer readable medium of any one of clauses 181 to 184, wherein information obtained by monitoring the primary beam of charged particles is at least one of:
a fluctuation of a source tip current,
an angular distribution of a tip emitted-current density,
a virtual source tip position,
a long-term source tip drift, or
an emission fluctuation.

186. The non-transitory computer readable medium of any one of clauses 177 to 185, wherein information obtained by monitoring the characteristic of the charged particle source is used to normalize detection data from the image detector.

187. The non-transitory computer readable medium of any one of clauses 177 to 186, wherein measuring the characteristic of the secondary charged particle comprises measuring a landing event of the secondary charged particle.

188. The non-transitory computer readable medium of clause 187, wherein the image detector measures a number of secondary charged particles impacting the image detector during the landing event.

189. The non-transitory computer readable medium of clause 187 or 188, wherein measuring the characteristic of the secondary charged particle comprises measuring a timestamp of the landing event.

190. The non-transitory computer readable medium of clause 189, further comprising determining a current on a surface of the sample based on the landing event and the timestamp.

191. The non-transitory computer readable medium of any one of clauses 177 to 190, wherein applying the determined characteristic of the charged particle source to the image detector normalizes detection data of the image detector.

192. The non-transitory computer readable medium of any one of clauses 177 to 190, wherein applying the determined characteristic of the charged particle source to the image detector improves a signal-to-noise ratio of the compensated image.

193. The non-transitory computer readable medium of any one of clauses 177 to 190, wherein applying the determined characteristic of the charged particle source to the image detector improves a brightness of the compensated image.

194. The non-transitory computer readable medium of any one of clauses 177 to 190, wherein applying the determined characteristic of the charged particle source to the image detector improves a contrast of the compensated image.

195. The non-transitory computer readable medium of any one of clauses 177 to 191, wherein applying the determined characteristic of the charged particle source to the image detector improves metrology measurement and inspection measurement accuracy of the compensated image.

196. The non-transitory computer readable medium of any one of clauses 177 to 195, wherein the charged particle system is a scanning electron microscope.

197. A non-transitory computer readable medium comprising a set of instructions that is executable by one or more processors of a computing device to cause the computing device to perform operations for compensating for variations in charged particle beam current in generation of an image of a sample, the operations comprising:
causing a charged particle source to emit a primary beam of charged particles in a charged particle system;
monitoring a characteristic of the charged particle source, wherein the characteristic of the charged particle source affects an emission of the primary beam of charged particles;
determining whether the characteristic of the charged particle source has deviated from a threshold value;
in response to the determination that the characteristic of the charged particle source has deviated from the threshold value, dynamically adjusting scanning the primary beam of charged particles over the sample based on the deviated characteristic of the charged particle source; and
generating a compensated image by collecting secondary charged particles emitted from the sample via scanning the primary beam of charged particles over the sample via an image detector.

198. The non-transitory computer readable medium of clause 197, wherein monitoring the characteristic of the charged particle source comprises directly measuring the charged particle source.

199. The non-transitory computer readable medium of clause 198, wherein the characteristic of the charged particle source is an emission current value.

200. The non-transitory computer readable medium of clause 197, wherein monitoring the characteristic of the charged particle source comprises indirectly measuring the charged particle source.

201. The non-transitory computer readable medium of clause 200, wherein the characteristic of the charged particle source is measured by monitoring the primary beam of charged particles.

202. The non-transitory computer readable medium of clause 201, wherein an auxiliary detector positioned at a downstream location of the charged particle source monitors a parameter of the primary beam of charged particles.

203. The non-transitory computer readable medium of clause 202, wherein the auxiliary detector includes circuitry configured to continuously monitor the parameter of the primary beam of charged particles.

204. The non-transitory computer readable medium of any one of clauses 201 to 203, wherein information obtained by monitoring the primary beam of charged particles is attributed to the charged particle source.

205. The non-transitory computer readable medium of any one of clauses 201 to 204, wherein information obtained by monitoring the primary beam of charged particles is at least one of:
a fluctuation of a source tip current,
an angular distribution of a tip emitted-current density,
a virtual source tip position,
a long-term source tip drift, or
an emission fluctuation.

206. The non-transitory computer readable medium of any one of clauses 197 to 205, wherein information obtained by monitoring the characteristic of the charged particle source is used to normalize detection data from the image detector.

207. The non-transitory computer readable medium of any one of clauses 197 to 206, wherein dynamically adjusting scanning the primary beam of charged particles over the sample comprises:
applying an electrical signal at a rate of a first magnitude when the characteristic value of the charged particle source has deviated above a target threshold value; and
applying an electrical signal at a rate of a second magnitude when the characteristic value of the charged particle source has deviated below a target threshold value.

208. The non-transitory computer readable medium of clause 207, wherein dynamically adjusting scanning the primary beam of charged particles increases a scan speed across the sample.

209. The non-transitory computer readable medium of clause 207, wherein dynamically adjusting scanning the primary beam of charged particles decreases a scan speed across the sample.

210. The non-transitory computer readable medium of any one of clauses 207 to 209, wherein the electrical signal is a voltage.

211. The non-transitory computer readable medium of any one of clauses 207 to 209, wherein the electrical signal is a current.

212. The non-transitory computer readable medium of any one of clauses 197 to 211, wherein dynamically adjusting scanning the primary beam of charged particles is maintained at a constant dose of charged particles per area on the sample.

213. The non-transitory computer readable medium of clause 212, wherein the area on the sample is a pixel.

214. The non-transitory computer readable medium of any one of clauses 197 to 213, wherein the compensated image has an improved signal-to-noise ratio.

215. The non-transitory computer readable medium of any one of clauses 197 to 213, wherein the compensated image has an improved brightness.

216. The non-transitory computer readable medium of any one of clauses 197 to 213, wherein the compensated image has an improved contrast.

217. The non-transitory computer readable medium of any one of clauses 197 to 216, wherein the compensated image is used for defect inspection of the sample.

218. The non-transitory computer readable medium of any one of clauses 197 to 216, wherein the compensated image is used to collect a metrology measurement.

219. The non-transitory computer readable medium of any one of clauses 197 to 218, wherein the charged particle system is a scanning electron microscope.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. An apparatus for inspecting a sample, comprising:
a charged particle source configured to emit a primary beam of charged particles;
an aperture substrate comprising:
a first set of apertures configured to form a first set of charged particle beamlets by passing through a portion of charged particles of the primary beam of charged particles; and
a second aperture configured to form a second charged particle beamlet by passing through another portion of charged particles of the primary beam of charged particles, wherein the second charged particle beamlet is active at a same time as the first set of charged particle beamlets, and the first set of charged particle beamlets and second charged particle beamlet have no beamlet in common;
one or more first detectors to detect secondary charged particles emitted in response to the first set of charged particle beamlets impacting the sample;
an auxiliary detector configured to monitor the second charged particle beamlet, wherein the second charged particle beamlet is directed to the auxiliary detector without interacting with the sample; and
an image processor configured to generate an image based on detection data from the one or more first detectors and based on detection data from the auxiliary detector.

2. The apparatus of claim 1, further comprising an objective lens configured to focus the first set of charged particle beamlets to a focal point substantially at the sample, wherein the second charged particle beamlet is not focused by the objective lens.

3. The apparatus of claim 1, wherein the second aperture is positioned at a minimum distance from the first set of apertures on the aperture substrate.

4. The apparatus of claim 1, wherein the second aperture is positioned between the first set of apertures on the aperture substrate.

5. The apparatus of claim 1, wherein the auxiliary detector is configured to obtain information about a parameter of the second charged particle beamlet.

6. The apparatus of claim 5, wherein the auxiliary detector is configured to continuously monitor the parameter of the second charged particle beamlet.

7. The apparatus of claim 1, wherein the auxiliary detector comprises a plurality of segments to monitor the second charged particle beamlet.

8. The apparatus of claim 5, wherein the parameter of the second charged particle beamlet is related to a corresponding parameter of the first set of charged particle beamlets.

9. The apparatus of claim 8, wherein the parameter of the second charged particle beamlet is off-axis aberration.

10. The apparatus of claim 8, wherein the obtained information about the parameter of the second charged particle beamlet is attributed to the charged particle source.

11. The apparatus of claim 5, wherein the parameter of the second charged particle beamlet is at least one of:
a fluctuation of a source tip current,
an angular distribution of a tip emitted-current density,
a virtual source tip position,
a long-term source tip drift, or
an emission fluctuation.

12. The apparatus of claim 1, wherein the detection data from the auxiliary detector is used to normalize the detection data from the one or more first detectors.

13. The apparatus of claim 4-2, wherein the auxiliary detector is located between an up-beam surface of the aperture substrate and the objective lens.

14. The apparatus of claim 1, wherein the auxiliary detector placed on a same vertical axis of the second aperture.

15. A non-transitory computer readable medium storing a set of instructions that is executable by one or more processors of a charged particle beam apparatus to cause the charged particle beam apparatus to perform a method of inspecting a sample, the method comprising:
causing a charged particle source to emit a primary beam of charged particles;
forming a first set of charged particle beamlets using a first set of apertures on an aperture substrate by passing a portion of charged particles of the primary beam of charged particles through the first set of apertures, wherein secondary charged particles emitted in response to the first set of charged particle beamlets impacting the sample are detected by one or more first detectors;
focusing the first set of charged particle beamlets using an objective lens to a focal point substantially at the sample;
forming a second charged particle beamlet using a second aperture on the aperture substrate by passing a portion of charged particles of the primary beam of charged particles through the second aperture, wherein the second charged particle beamlet is active at a same time as the first set of charged particle beamlets and is directed to an auxiliary detector without interacting with the sample, and the first set of charged particle beamlets and the second charged particle beamlet have no beamlet in common; and
generating an image based on detection data from the one or more first detectors and based on detection data from the auxiliary detector.

16. The non-transitory computer readable medium of claim 15, wherein the second charged particle beamlet is not focused by the objective lens.

17. The non-transitory computer readable medium of claim 15, wherein the aperture substrate is a top layer of a layered structure comprising a plurality of layered optical elements.

18. The non-transitory computer readable medium of claim 15, wherein the second aperture is positioned between the first set of apertures on the aperture substrate.

19. The non-transitory computer readable medium of claim 15, wherein the set of instructions that is executable by the one or more processors to cause the charged particle beam apparatus to further perform:
obtaining information about a parameter of the second charged particle beamlet using the auxiliary detector.

20. An apparatus for compensating for variations in charged particle beam current in generation of an image of a sample, comprising:
a charged particle source configured to emit a primary beam of charged particles;
a monitoring component including circuitry configured to monitor a characteristic of the charged particle source and to determine whether the characteristic of the charged particle source has deviated from a threshold value, wherein the characteristic of the charged particle source affects an emission of the primary beam of charged particles;
an image detector configured to measure a characteristic for a secondary charged particle emitted from the sample via scanning the primary beam of charged particles over the sample; and
an image processor including circuitry configured to determine a characteristic of the charged particle source based on the measured characteristic of the secondary charged particle to compensate for the deviated characteristic of the charged particle source, if the characteristic of the charged particle source has deviated from the threshold value and to generate a compensated image of the sample based on the determined characteristic of the charged particle source.
